(19) United States
(12) Patent Application Publication
(10) Pub. No.: US 2025/0233576 A1
(43) Pub. Date: Jul. 17, 2025

(54) VIBRATION ELEMENT, VIBRATION ELEMENT ARRAY, AND ELECTRONIC APPARATUS

(71) Applicant: SONY GROUP CORPORATION, TOKYO (JP)

(72) Inventors: TAKUMA MATSUSHITA, TOKYO (JP); TAKASHI KAWAMURA, TOKYO (JP)

(21) Appl. No.: 18/848,789

(22) PCT Filed: Feb. 3, 2023
(86) PCT No.: PCT/JP2023/003594

§ 371 Date: Sep. 19, 2024

(30) Foreign Application Priority Data
Mar. 29, 2022 (JP) 2022-053291

(51) Int. Cl. H03H 9/22; H01Q 1/22; H03H 3/06

(52) U.S. Cl. CPC H03H 9/22; H03H 3/06; H01Q 1/22

(57) ABSTRACT

To provide a vibration element having a structure capable of efficiently performing electric field-to-magnetic field conversion. The vibration element according to the present technology includes a vibration part in which a plurality of layers is laminated, the plurality of layers including a plurality of first elastic layers that is elastically deformed by electric field application, and at least one second elastic layer that is elastically deformed by magnetic field application. In accordance with the vibration element according to the present technology, a vibration element having a structure capable of efficiently performing electric field-to-magnetic field conversion can be provided. In accordance with the vibration element according to the present technology, a vibration element having a structure capable of efficiently performing electric field-to-magnetic field conversion can be provided.

### TECHNICAL FIELD

The technology according to the present disclosure (hereinafter, also referred to as “the present technology”) relates to a vibration element, a vibration element array, and an electronic apparatus.

### BACKGROUND ART

Conventionally, a magnetic field sensor with a magnetostrictive layer provided on a piezoelectric layer is known (e.g., see Patent Literature 1).

### CITATION LIST

### Patent Literature

Patent Literature 1: Japanese Patent Application Laid-open No. 2019-148503

### DISCLOSURE OF INVENTION

### Technical Problem

However, the conventional magnetic field sensor has no structure capable of efficiently performing electric field-to-magnetic field conversion.

In view of this, it is a main objective of the present technology to provide a vibration element having a structure capable of efficiently performing electric field-to-magnetic field conversion.

### Solution to Problem

The present technology provides a vibration element including
a vibration part in which a plurality of layers is laminated, the plurality of layers including
   a plurality of first elastic layers that is elastically deformed by electric field application, and
   at least one second elastic layer that is elastically deformed by magnetic field application.

The first elastic layers may each generate an electric field when the first elastic layers are elastically deformed by elastic deformation of the second elastic layer, and the second elastic layer may generate a magnetic field when the second elastic layer is elastically deformed by elastic deformation of the first elastic layer.

The first elastic layers do not need to be adjacent to each other.

The second elastic layer may include a plurality of second elastic layers, and the second elastic layers do not need to be adjacent to each other.

The plurality of layers may include a third elastic layer, and the first elastic layers may be arranged on both sides of the third elastic layer.

The second elastic layers may include a plurality of second elastic layers, and the second elastic layers may be arranged on both sides of a laminate part including the third elastic layer and the first elastic layers on the both sides of the third elastic layer.

The first and second elastic layers may be alternately laminated.

The first elastic layers may be arranged on both sides of the second elastic layer.

The plurality of layers may include third elastic layers arranged on both sides of a laminate part including the second elastic layer and first elastic layers on both sides of the second elastic layer.

The second elastic layers may be at least three second elastic layers, and the second elastic layers may be arranged on both sides of the laminate part including the second elastic layer and first elastic layers on both sides of the second elastic layer.

The first elastic layers may be arranged on both sides of a layer that is positioned in middle of the plurality of layers in a direction of lamination, and the first elastic layers may be different from each other in thickness and/or material.

The second elastic layer may include a plurality of second elastic layers, the second elastic layers may be arranged on both sides of a layer positioned in middle of the plurality of layers in a direction of lamination, and the second elastic layers may be different from each other in thickness and/or material.

The plurality of layers may include a resonance adjustment layer.

The vibration element may further include: a plurality of arm parts extending from the vibration part; and a supporting structure that supports the vibration part to be capable of vibrating via the plurality of arm parts.

The supporting structure may include a supporting member that has a recess part in which a part of the vibration part is arranged, and a portion including an extremity end of each of the plurality of arm parts may be connected to an opening end of the recess part.

The first elastic layers may each include a piezoelectric layer.

The second elastic layer may include a magnetic layer having magnetostrictive properties.

The third elastic layer may include a non-piezoelectric layer.

The second elastic layer may include a magnetic layer having magnetostrictive properties and an insulating layer, the magnetic layer and the insulating layer being alternately laminated.

The vibration element according to claim 1, in which the vibration element further includes a reflective layer bonded to the vibration part.

The vibration element may be an antenna element.

The vibration element may be operable in a band of 2.45 GHZ.

The present technology also provides a vibration element array including a plurality of vibration elements described above arranged in an array form.

The present technology also provides an electronic apparatus including the above-mentioned vibration element.

### BRIEF DESCRIPTION OF DRAWINGS

FIG. 1 A diagram showing a cross-sectional configuration of a vibration element according to Comparative Example 1.

FIG. 2 Equations representing Joule effect and Villari effect.

FIG. 3 A of FIG. 3 is a diagram for describing a relationship between a resonant frequency and a phase of the vibration element according to Comparative Example 1. B of FIG. 3 is a diagram for describing a relationship between a resonant frequency and a phase of a vibration element according to Comparative Example 2.

FIG. 4 A of FIG. 4 is a perspective view of a vibration element according to a first embodiment of the present technology. B of FIG. 4 is a diagram showing a cross-sectional configuration example of the vibration element according to the first embodiment of the present technology. C of FIG. 4 is a diagram for describing circuit properties of the vibration element according to the first embodiment of the present technology.

FIG. 5 A cross-sectional view of a vibration element according to Example 1 of the first embodiment of the present technology.

FIG. 6 A cross-sectional view of a vibration element according to Example 2 of the first embodiment of the present technology.

FIG. 7 A plan view of the vibration element according to Example 2 of the first embodiment of the present technology.

FIG. 8 A block diagram showing functions of the vibration element according to Example 2 of the first embodiment of the present technology.

FIG. 9 A of FIG. 9 is a view showing a mounting example of the vibration element according to Example 2 of the first embodiment of the present technology. B of FIG. 9 is a view showing a mounting example of a conventional antenna element.

FIG. 10 A flowchart for describing an example of a manufacturing method for the vibration element according to Example 2 of the first embodiment of the present technology.

FIG. 11 A of FIG. 11 is a cross-sectional view for each step of an example of the manufacturing method for the vibration element according to Example 2 of the first embodiment of the present technology. B of FIG. 11 is a plan view for each step of an example of the manufacturing method for the vibration element according to Example 2 of the first embodiment of the present technology.

FIG. 12 A of FIG. 12 is a cross-sectional view for each step of an example of the manufacturing method for the vibration element according to Example 2 of the first embodiment of the present technology. B of FIG. 12 is a plan view for each step of an example of the manufacturing method for the vibration element according to Example 2 of the first embodiment of the present technology.

FIG. 13 A of FIG. 13 is a cross-sectional view for each step of an example of the manufacturing method for the vibration element according to Example 2 of the first embodiment of the present technology. B of FIG. 13 is a plan view for each step of an example of the manufacturing method for the vibration element according to Example 2 of the first embodiment of the present technology.

FIG. 14 A of FIG. 14 is a cross-sectional view for each step of an example of the manufacturing method for the vibration element according to Example 2 of the first embodiment of the present technology. B of FIG. 14 is a plan view for each step of an example of the manufacturing method for the vibration element according to Example 2 of the first embodiment of the present technology.

FIG. 15 A of FIG. 15 is a cross-sectional view for each step of an example of the manufacturing method for the vibration element according to Example 2 of the first embodiment of the present technology. B of FIG. 15 is a plan view for each step of an example of the manufacturing method for the vibration element according to Example 2 of the first embodiment of the present technology.

FIG. 16 A of FIG. 16 is a cross-sectional view for each step of an example of the manufacturing method for the vibration element according to Example 2 of the first embodiment of the present technology. B of FIG. 16 is a plan view for each step of an example of the manufacturing method for the vibration element according to Example 2 of the first embodiment of the present technology.

FIG. 17 A of FIG. 17 is a cross-sectional view for each step of an example of the manufacturing method for the vibration element according to Example 2 of the first embodiment of the present technology. B of FIG. 17 is a plan view for each step of an example of the manufacturing method for the vibration element according to Example 2 of the first embodiment of the present technology.

FIG. 18 A of FIG. 18 is a cross-sectional view for each step of an example of the manufacturing method for the vibration element according to Example 2 of the first embodiment of the present technology. B of FIG. 18 is a plan view for each step of an example of the manufacturing method for the vibration element according to Example 2 of the first embodiment of the present technology.

FIG. 19 A of FIG. 19 is a cross-sectional view for each step of an example of the manufacturing method for the vibration element according to Example 2 of the first embodiment of the present technology. B of FIG. 19 is a plan view for each step of an example of the manufacturing method for the vibration element according to Example 2 of the first embodiment of the present technology.

FIG. 20 A of FIG. 20 is a diagram showing stress/frequency characteristics of the vibration element according to Comparative Example 1. B of FIG. 20 is a diagram showing stress/frequency characteristics of the vibration element according to Example 2 of the first embodiment of the present technology.

FIG. 21 A of FIG. 21 is a diagram showing a frequency of a resonance point of the vibration element according to Comparative Example 1. B of FIG. 21 is a diagram showing a frequency of a resonance point of the vibration element according to Example 2 of the first embodiment of the present technology.

FIG. 22 A cross-sectional view of a vibration element according to a second embodiment of the present technology.

FIG. 23 A cross-sectional view of a vibration element according to a third embodiment of the present technology.

FIG. 24 A cross-sectional view of a vibration element according to a fourth embodiment of the present technology.

FIG. 25 A of FIG. 25 is a plan view of a vibration element according to of Example 1 of the fourth embodiment of the present technology. B of FIG. 25 is a plan view of a vibration element according to of Example 2 of the fourth embodiment of the present technology.

FIG. 26 A cross-sectional view of a vibration element according to a fifth embodiment of the present technology.

FIG. 27 A cross-sectional view of the vibration element according to a sixth embodiment of the present technology.

FIG. 28 A of FIG. 28 is a cross-sectional view of the vibration element according to Example 1 of the sixth embodiment of the present technology. B of FIG. 28 is a cross-sectional view of the vibration element according to Example 2 of the sixth embodiment of the present technology.

FIG. 29 A cross-sectional view of a vibration element according to Example 1 of a seventh embodiment of the present technology.

FIG. 30 A cross-sectional view of a vibration element according to Example 2 of the seventh embodiment of the present technology.

FIG. 31 A cross-sectional view of a vibration element according to Example 3 of the seventh embodiment of the present technology.

FIG. 32 A cross-sectional view of a vibration element according to Example 1 of an eighth embodiment of the present technology.

FIG. 33 A cross-sectional view of a vibration element according to Example 2 of the eighth embodiment of the present technology.

FIG. 34 A cross-sectional view of a vibration element according to Example 3 of the eighth embodiment of the present technology.

FIG. 35 A of FIG. 35 is a perspective view of an array of vibration elements according to Example 1 of a ninth embodiment of the present technology. B of FIG. 35 is a perspective view of an array of vibration elements according to Example 2 of the ninth embodiment of the present technology.

FIG. 36 A cross-sectional view of a vibration element according to a tenth embodiment of the present technology.

FIG. 37 A of FIG. 37 is a plan view of a vibration element according to Example 1 of the tenth embodiment of the present technology. B of FIG. 37 is a plan view of a vibration element according to Example 2 of the tenth embodiment of the present technology. C of FIG. 37 is a plan view of a vibration element according to Example 3 of the tenth embodiment of the present technology. D of FIG. 37 is a plan view of a vibration element according to Example 4 of the tenth embodiment of the present technology.

FIG. 38 A of FIG. 38 is a plan view of a vibration element according to Example 5 of the tenth embodiment of the present technology. B of FIG. 38 is a plan view of a vibration element according to Example 6 of the tenth embodiment of the present technology. C of FIG. 38 is a plan view of a vibration element according to Example 7 of the tenth embodiment of the present technology.

FIG. 39 A of FIG. 39 is a plan view of a vibration element according to Example 8 of the tenth embodiment of the present technology. B of FIG. 39 is a plan view of a vibration element according to Example 9 of the tenth embodiment of the present technology.

FIG. 40 A of FIG. 40 is a cross-sectional view of a vibration element according to Example 10 of the tenth embodiment of the present technology. B of FIG. 40 is a cross-sectional view of a vibration element according to Example 11 of the tenth embodiment of the present technology. C of FIG. 40 is a cross-sectional view of a vibration element according to Example 12 of the tenth embodiment of the present technology.

FIG. 41 A cross-sectional view of a vibration element according to Example 1 of an eleventh embodiment of the present technology.

FIG. 42 A cross-sectional view of a vibration element according to Example 2 of the eleventh embodiment of the present technology.

FIG. 43 A cross-sectional view of a vibration element according to Example 3 of the eleventh embodiment of the present technology.

FIG. 44 A cross-sectional view of a vibration element according to Example 4 of the eleventh embodiment of the present technology.

FIG. 45 A cross-sectional view of a vibration element according to a twelfth embodiment of the present technology.

### MODE(S) FOR CARRYING OUT THE INVENTION

Hereinafter, favorable embodiments of the present technology will be described in detail with reference to the accompanying drawings. It should be noted that in this specification and the drawings, components having substantially the same functions and configurations will be denoted by the same reference signs and duplicate descriptions thereof will be omitted. The embodiments described below are representative embodiments of the present technology, and the scope of the present technology should not be construed narrowly by them. Even in a case where it is described in this specification that a vibration element, a vibration element array, and an electronic apparatus according to the present technology produce multiple effects, the vibration element, the vibration element array, and the electronic apparatus according to the present technology only need to produce at least one effect. The effects described in this specification are examples only and are not limited, and other effects may be provided.

Moreover, the descriptions will be given in the following order.
0. Introduction
1. Vibration Element According to First Embodiment of Present Technology
2. Vibration Element According to Second Embodiment of Present Technology
3. Vibration Element According to Third Embodiment of Present Technology
4. Vibration Element According to Fourth embodiment of Present Technology
5. Vibration Element According to Fifth Embodiment of Present Technology
6. Vibration Element According to Sixth Embodiment of Present Technology
7. Vibration Element According to Seventh Embodiment of Present Technology
8. Vibration Element According to Eighth Embodiment of Present Technology
9. Array of Vibration Element According to Ninth Embodiment of Present Technology
10. Vibration Element According to Tenth Embodiment of Present Technology
11. Vibration Element According to Eleventh Embodiment of Present Technology
12. Vibration Element According to Twelfth Embodiment of Present Technology

### <0. Introduction>

Conventionally, a vibration element (e.g., an antenna element) with a resonator such as a solidly mounted resonator (SMR) or a film bulk acoustic resonator (FBAR) is known. However, the conventional vibration element does not have a structure capable of efficiently performing electric field-to-magnetic field conversion. Since the vibration element having such a structure can achieve downsizing and high performance, it is extremely useful especially for being mounted on a compact electronic apparatus (e.g., a mobile apparatus such as earphones, a smartwatch, a smartphone, or an IoT device) for which the installation space is limited.

In view of this, after careful consideration, the inventors have developed a vibration element according to the present technology as a vibration element having a structure capable of efficiently performing electric field-to-magnetic field conversion.

### [Vibration Element According to Comparative Example]

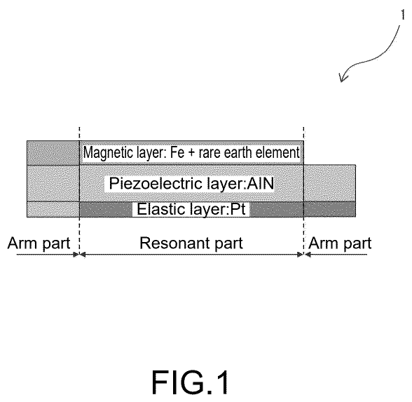

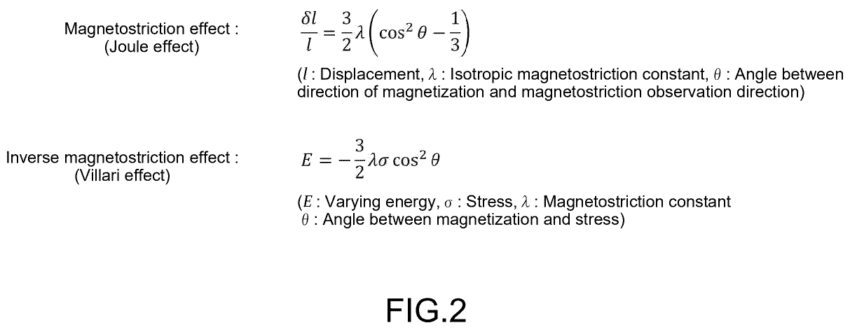

FIG. 1 is a view showing a cross-sectional configuration of a vibration element (e.g., an antenna element) according to Comparative Example 1. FIG. 2 is equations representing Joule effect and Villari effect.

As shown in FIG. 1, in a vibration element 1 according to Comparative Example 1, a magnetic layer (e.g., FeGaB layer) having magnetostrictive properties on a piezoelectric layer (e.g., AlN layer) is provided. The magnetic layer serves as an electrode. For example, an electrode formed of Pt is provided on the lower surface of the piezoelectric layer. That is, the vibration element 1 has a configuration in which the piezoelectric layer is sandwiched by two electrodes. As shown in FIG. 1, the vibration element 1 includes a resonant part (vibration part) in middle of an in-plane direction and includes a plurality (e.g., two) of arm parts extending outwards from the resonant part in a periphery in the in-plane direction. To be specific, the vibration element 1 is an FBAR resonator with an unimorph structure having a resonant frequency of 2.3025 GHZ.

### (Time of Receiving)

In the vibration element 1, surrounding electromagnetic waves enter the magnetic layer at the time of receiving. At this time, magnetostriction is generated in the magnetic layer due to the Joule effect (see FIG. 2) and distortion occurs throughout the vibration element 1. At this time, voltage is output from a piezoelectric element due to a positive piezoelectric effect.

### (Time of Sending)

In the vibration element 1, voltage is applied on the piezoelectric layer at the time of sending. At this time, magnetostriction is generated in the piezoelectric layer due to the inverse piezoelectric effect and distortion occurs throughout the vibration element 1. At this time, the magnetization of the magnetic layer periodically changes due to the Villari effect (see FIG. 2). The periodic magnetization change causes the surrounding magnetic field.

### (Problem and Solution)

In the vibration element according to Comparative Example 1, gain, which is a ratio of output to input, does not reach a required level. In order to obtain high gain, it is necessary to increase magnetization. The following two methods are effective as methods for increasing the magnetization.
1. To increase distortion of the entire vibration element, thereby increasing Villari effect
2. To increase volume of the magnetic layer itself, thereby increasing magnetization (increasing magnetization M by the original volume).

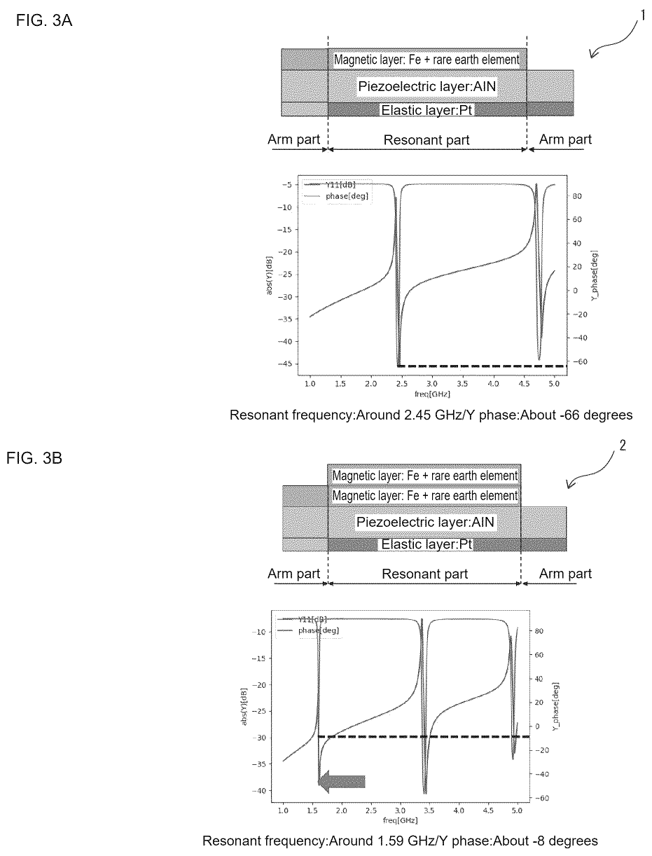

A of FIG. 3 is a diagram for describing a relationship between a resonant frequency and a phase of the vibration element according to Comparative Example 1. In the vibration element 1, the phase is-66 degrees near a resonant frequency of 2.45 GHZ.

B of FIG. 3 is a diagram for describing a relationship between a resonant frequency and a phase of a vibration element according to Comparative Example 2. A vibration element 2 according to Comparative Example 2 shown in B of FIG. 3 has a configuration in which the thickness of the magnetic layer of the vibration element 1 according to Comparative Example 1 shown in A of FIG. 3 is twice. In the vibration element 2, the phase is-8 degrees near a resonant frequency of 1.59 GHz, and the resonant frequency changes with respect to the vibration element 1 and the amplitude decreases. In this manner, even if the thickness of the magnetic layer of the vibration element 1 according to Comparative Example 1 is simply increased, a larger amplitude, i.e., larger gain cannot be obtained at the same resonant frequency (desired resonant frequency). It should be noted that it has been confirmed that the resonant frequency of the vibration element does not significantly change only due to structural (mechanical) differences.

### [1. Vibration Element According to First Embodiment of Present Technology]

### <<Configuration of Vibration Element According to First Embodiment>>

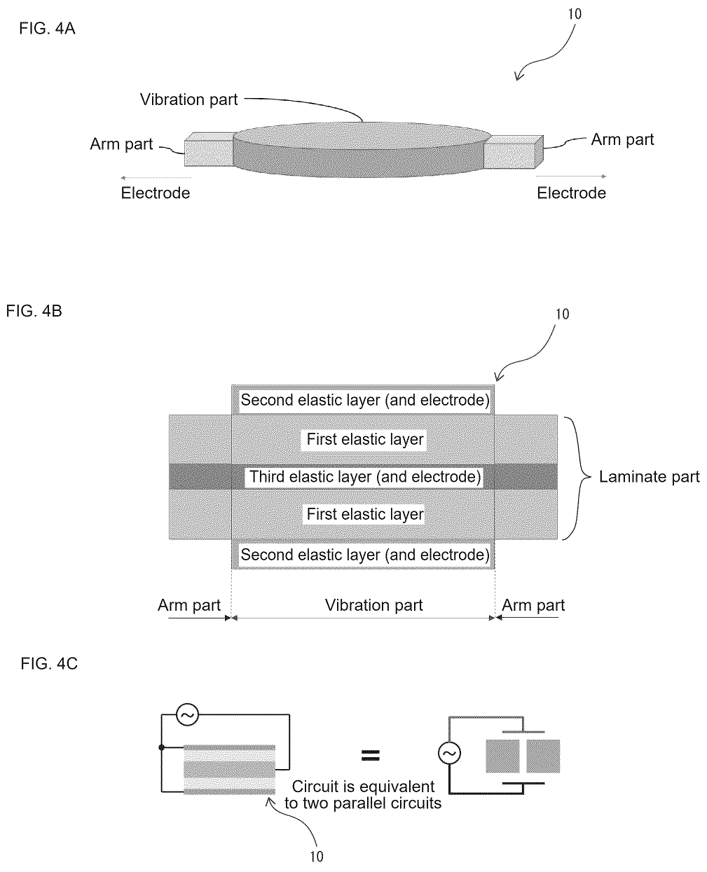

A of FIG. 4 is a perspective view of a vibration element according to a first embodiment of the present technology. B of FIG. 4 is a diagram showing a cross-sectional configuration example of the vibration element according to the first embodiment of the present technology. C of FIG. 4 is a diagram for describing circuit properties of the vibration element according to the first embodiment of the present technology. Hereinafter, the description will be made assuming that the upper side is upper and the lower side is lower in a diagram and a cross-sectional view showing a cross-sectional configuration example, for the sake of convenience.

A vibration element 10 is an antenna element as an example. The vibration element 10 is operable near the band of 2.45 GHZ (a frequency band corresponding to the Bluetooth (registered trademark) communication standard) as an example. That is, the vibration element 10 is designed to have a resonant frequency in the 2.45 GHz band as an example. It should be noted that the vibration element 10 can also be designed so that the resonant frequency is in the frequency band below 2.45 GHz or above 2.45 GHZ.

As shown in B of FIG. 4, the vibration element 10 includes a vibration part (resonant part) in which a plurality of (e.g., five) layers is laminated, the plurality of (e.g., five) layers including a plurality of (e.g., two) first elastic layers which is elastically deformed by electric field application and at least one second elastic layer (e.g., two second elastic layers) which is (are) elastically deformed by magnetic field application. The plurality of layers of the vibration element 10 further includes a third elastic layer as a base layer and the first elastic layers are arranged on both sides of the third elastic layer.

In the vibration element 10, the first elastic layers are not adjacent to each other. In the vibration element 10, the second elastic layers are not adjacent to each other. In the vibration element 10, the second elastic layers are arranged on both sides of a laminate part including the third elastic layer and the first elastic layers on the both sides of the third elastic layer.

As shown in A of FIG. 4, the vibration element 10 includes a plurality of (e.g., two) arm parts extending outwards from the vibration part. In the example of A of FIG. 4, the vibration element 10 includes an arm part extending outwards from one of two opposite end portions of the vibration part in the in-plane direction and an arm part extending outwards from the other of the two end portions in the in-plane direction. An end portion of each arm part, which is located on a side opposite to the vibration element 10 side, can be supported by the supporting structure. An electrode is provided on an extremity end side of each arm part.

In the vibration element 10, the third elastic layer between the two first elastic layers can be a common electrode and be connected to one terminal of a power supply and the two second elastic layers can be short-circuited and be connected to the other terminal of the power supply. That is, the circuit including the vibration element 10 and the power supply is equivalent to two parallel circuits as shown in C of FIG. 4.

The first elastic layers generate an electric field when elastically deformed by the second elastic layers and the second elastic layers generate a magnetic field when elastically deformed by the first elastic layers. The first elastic layers can include for example piezoelectric layers. The second elastic layers can include for example magnetic layers (also referred to as magnetostrictive layers) having magnetostrictive properties. The third elastic layer can include for example a non-piezoelectric layer.

Examples of the material for the piezoelectric layer as an example of the first elastic layer include PZT, ZnO, AlN, AlScN, KNN, PVDF, PLA, quartz, LiNbO₃, and BaTiO₃. The thickness of each piezoelectric layer is for example approximately 1 to 1000 nm. It should be noted that the thickness of each piezoelectric layer is favorably at least ½ or ¼ times an elastic wavelength depending on physical properties of each layer.

Materials for the magnetic layer with magnetostrictive properties as an example of the second elastic layer are favorably materials that are conductive, have a non-zero magnetostriction constant, and have a high magnetic permeability. Examples of the materials include iron-based magnetic materials, electromagnetic steel sheets, permalloy, permendur, FeNi/Al/Co alloys, FeAlSi alloys, ferrites, and amorphous nanocrystalline magnetic materials. More specifically, examples of the materials include Ni, Fe-based metal magnetic materials such as Ni, Ni—Co alloy, Ni—Co—Cr alloy, Ni—Fe alloy, Fe—Co alloy, Fe—Al alloy, and Fe—Co alloy, and ferrite-based magnetic materials such as Ni ferrite, Ni—Co ferrite, and Ni—Cu—Co ferrite. The thickness of each magnetic layer is for example approximately 1 to 1000 nm.

Materials of the base layer as an example of the third elastic layer are favorably non-piezoelectric materials that are conductive. Examples of the materials include Mo, Pt, Al, Cu, Au, and Ag. The thickness of the base layer is for example approximately 50 to 200 nm.

### <<Operation of Vibration Element According to First Embodiment>>

The vibration element 10 performs an operation substantially similar to an operation of the above-mentioned vibration element 1 according to Comparative Example 1 (a bimorph operation using the third elastic layer (base layer) as a center) at the time of receiving/sending.

### Example 1

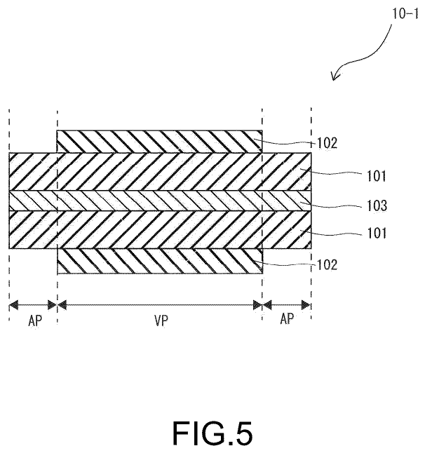

FIG. 5 is a cross-sectional view of a vibration element 10-1 according to Example 1 of the first embodiment of the present technology. As shown in FIG. 5, the vibration element 10-1 includes a vibration part VP in which five layers are laminated, the five layers including two first elastic layers 101 which is elastically deformed by electric field application and two second elastic layers 102 which is elastically deformed by magnetic field application. The vibration element 10-1 includes an arm part AP extending outwards from one of two opposite end portions of the vibration part VP and an arm part AP extending outwards from the other. In the vibration element 10-1, as an example, the respective first elastic layers 101 are set to have the same thickness and the respective second elastic layers 102 are set to have the same thickness. Each first elastic layer 101 can include a piezoelectric layer, for example. Each second elastic layer 102 can include for example a magnetic layer having magnetostrictive properties. Hereinafter, in a case where the first elastic layer 101 on the upper side includes a piezoelectric layer, the piezoelectric layer will be also referred to as an upper piezoelectric layer. In a case where the first elastic layer 101 on the lower side includes a piezoelectric layer, the piezoelectric layer will be also referred to as a lower piezoelectric layer. In a case where the second elastic layer 102 on the upper side includes a magnetic layer having magnetostrictive properties, the magnetic layer will be also referred to as an upper magnetic layer. In a case where the second elastic layer 102 on the lower side includes a magnetic layer having magnetostrictive properties, the magnetic layer will be also referred to as a lower magnetic layer.

### Example 2

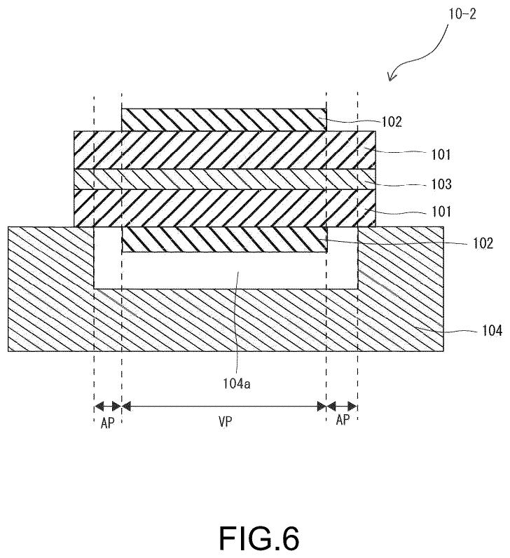

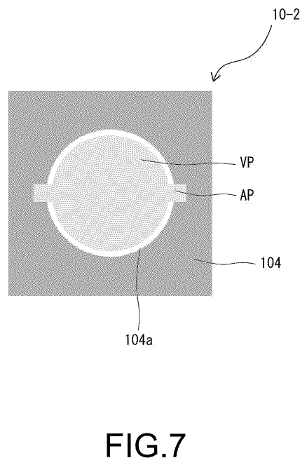

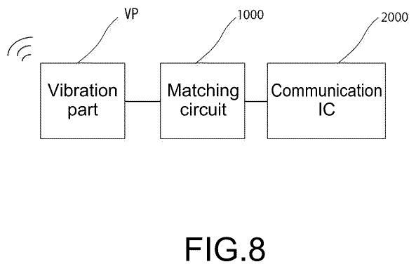

FIG. 6 is a cross-sectional view of a vibration element 10-2 according to Example 2 of the first embodiment of the present technology. FIG. 7 is a plan view of the vibration element 10-2 according to Example 2 of the first embodiment of the present technology. FIG. 8 is a block diagram showing functions of the vibration element 10-2 according to Example 2 of the first embodiment of the present technology. As shown in FIGS. 6 and 7, the vibration element 10-2 has a configuration similar to that of the vibration element 10-1 according to Example 1 except for the point that the vibration element 10-2 includes a supporting structure that supports the vibration part VP to be capable of vibrating via the plurality of arm parts AP. The supporting structure includes a substrate 104 serving as a supporting member having a recess part 104a in which a part of the vibration part VP is inserted. The extremity end portion of each of the plurality of arm parts AP is connected to the opening end of the recess part 104a. A lower end portion (e.g., a portion including the lower magnetic layer) of vibration part VP is arranged in the recess part 104a.

As shown in FIG. 8, the vibration element 10-2 can configure a communication apparatus by being combined with a matching circuit 1000 connected to the vibration part VP and a communication IC connected to the matching circuit 1000. The matching circuit 1000 has a function (impedance matching function) of making the impedance of the vibration part VP equal to the impedance of the communication IC. The communication IC controls communication between the vibration element 10-2 and a control unit of an electronic apparatus in which the vibration element 10-2 is built.

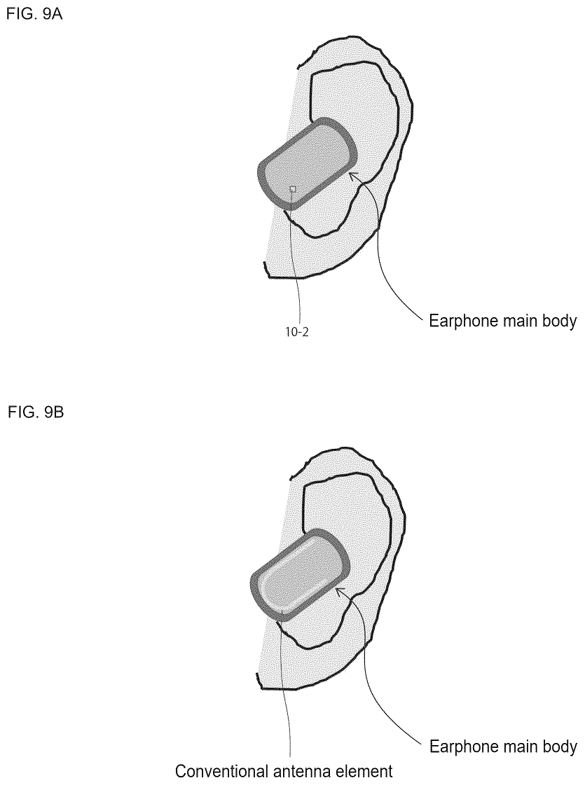

A of FIG. 9 is a view showing a mounting example of the vibration element 10-2 according to Example 2 of the first embodiment of the present technology. B of FIG. 9 is a view showing a mounting example of a conventional antenna element. Since the vibration element 10-2 is capable of obtaining high gain in an ultra-compact size as shown in A of FIG. 9, the vibration element 10-2 has an extremely high degree of freedom of installation and is excellent in space utility for example when the vibration element 10-2 is mounted on the main body of an earphone. On the other hand, the conventional antenna element requires a certain size (downsizing is limited) in order to obtain desired properties for example when it is mounted on the main body of the earphone as shown in B of FIG. 9, and requires a certain amount of space for installation.

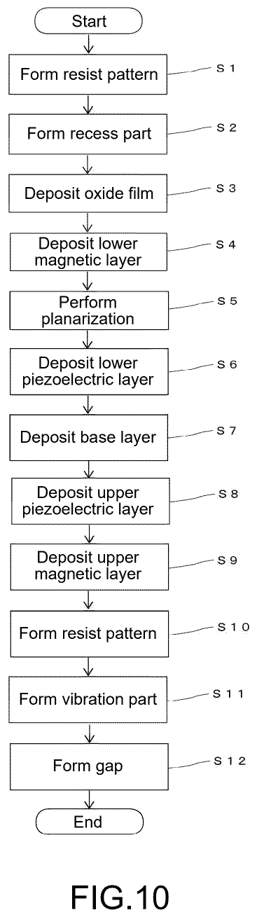

Hereinafter, a manufacturing method for the vibration element 10-2 according to Example 2 of the first embodiment of the present technology will be described with reference to the flowchart and the like in FIG. 10.

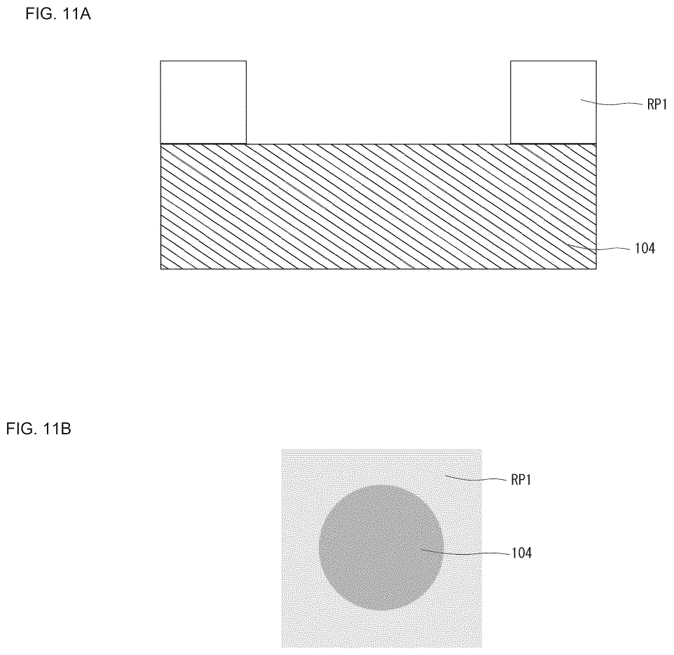

In first Step S1, a resist pattern RP1 is formed (see A of FIG. 11 and B of FIG. 11). Specifically, the resist pattern RP1 opened at a position at which the recess part 104a is formed is formed on the substrate 104.

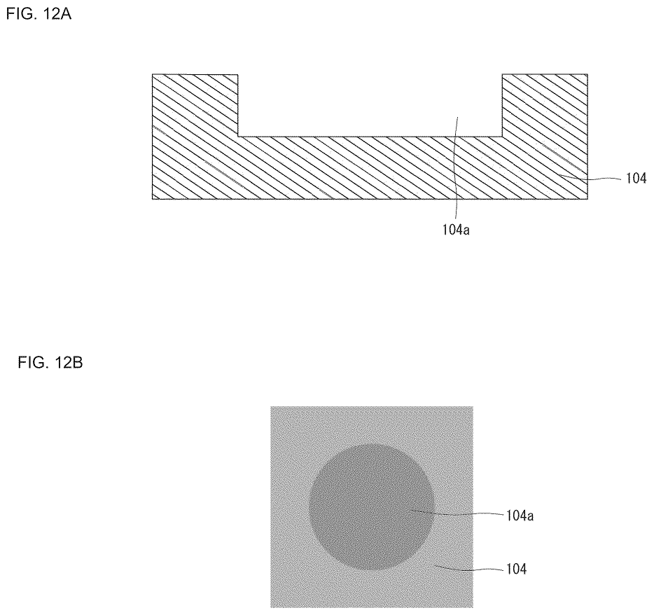

In next Step S2, the recess part 104a is formed (see A of FIG. 12 and B of FIG. 12). Specifically, the recess part 104a is formed by etching (e.g., dry etching) the substrate 104 to a predetermined depth (depth of the recess part 104a) using the resist pattern RP1 as a mask.

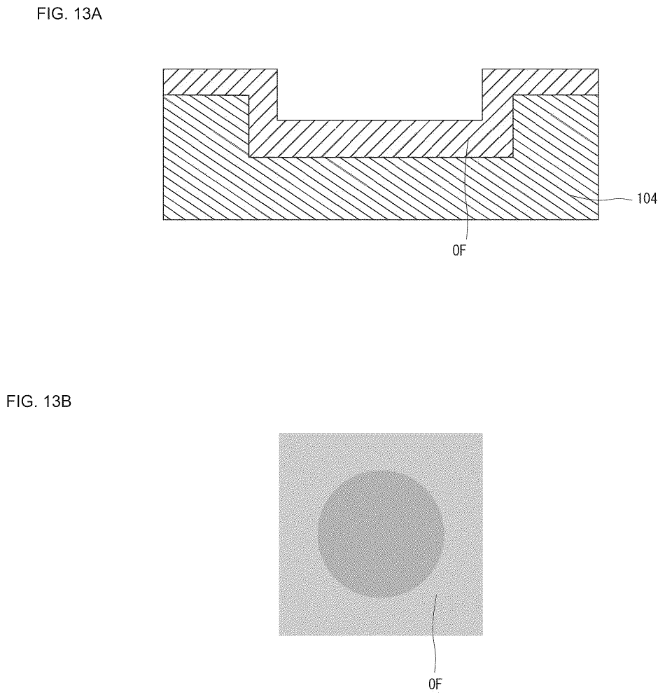

In next Step S3, an oxide film OF is deposited (see A of FIG. 13 and B of FIG. 13). Specifically, the oxide film OF is deposited on the entire surface of the substrate 104 in which the recess part 104a is formed to fill the space of the recess part 104a by a certain amount.

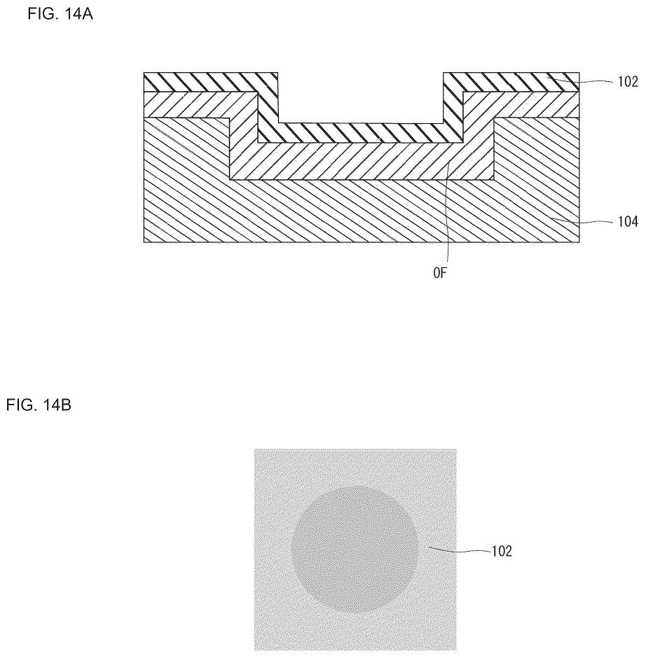

In next Step S4, a lower magnetic layer serving as the second elastic layer 102 on the lower side is deposited (see A of FIG. 14 and B of FIG. 14). Specifically, the lower magnetic layer is deposited to have for example a thickness of approximately 1 to 1000 nm on the entire surface by, for example, RF sputtering or magnetron sputtering.

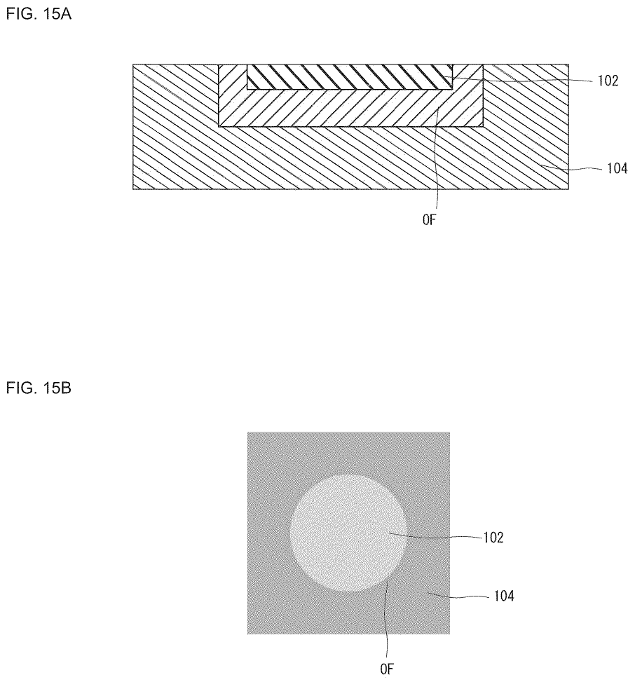

In next Step S5, planarization is performed (see A of FIG. 15 and B of FIG. 15). Specifically, by using a chemical mechanical polisher (CMP apparatus) for example, the entire surface is ground and planarized to the same height as the upper surface of the substrate 104.

In next Step S6, a lower piezoelectric layer serving as the first elastic layer 101 on the lower side is deposited. Specifically, the lower piezoelectric layer is deposited on the entire surface to have for example a thickness of approximately 25 to 1000 nm by sputtering, for example.

In next Step S7, a base layer serving as a non-piezoelectric third elastic layer 103 is deposited. Specifically, the base layer is deposited on the entire surface to have for example a thickness of approximately 50 to 200 nm by CVD, for example.

In next Step S8, an upper piezoelectric layer serving as the first elastic layer 101 on the upper side is deposited. Specifically, the upper piezoelectric layer is deposited on the entire surface to have for example a thickness of approximately 25 to 1000 nm by sputtering, for example.

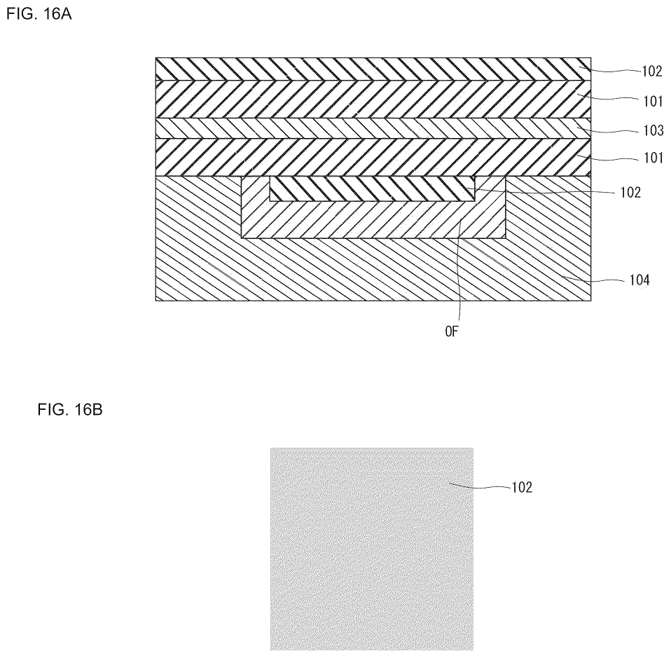

In next Step S9, an upper magnetic layer serving as the second elastic layer 102 on the upper side is deposited (see A of FIG. 16 and B of FIG. 16). Specifically, the upper magnetic layer is deposited to have for example a thickness of approximately 1 to 1000 nm on the entire surface by, for example, RF sputtering or magnetron sputtering to form a laminate.

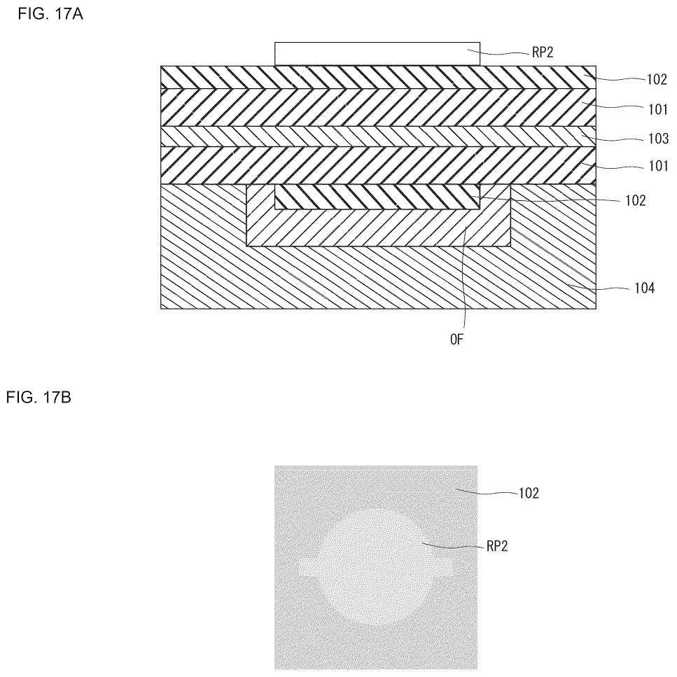

In next Step S10, a resist pattern RP2 is formed (see A of FIG. 17 and B of FIG. 17). Specifically, the resist pattern RP2 that covers the position at which the vibration part VP is formed is formed on the laminate.

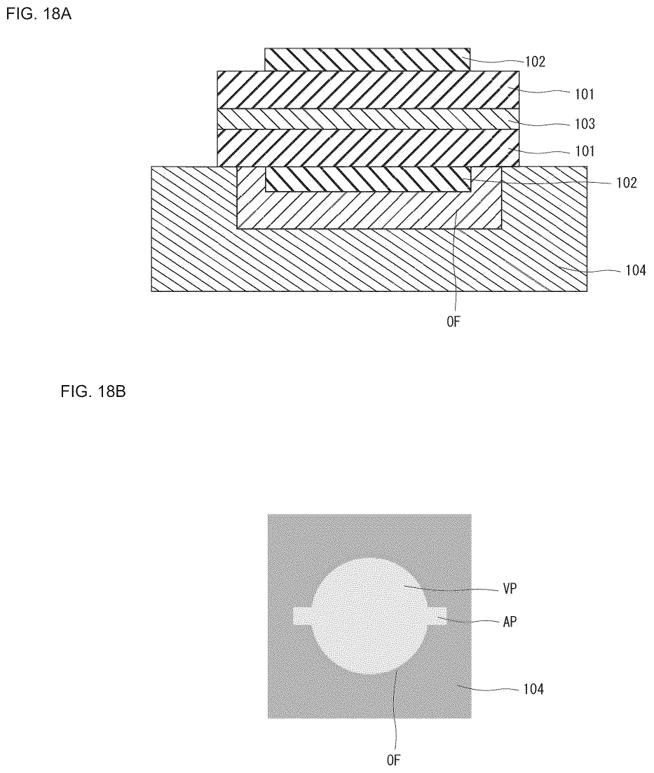

In next Step S11, the vibration part VP is formed (see A of FIG. 18 and B of FIG. 18). Specifically, the vibration part VP is formed by etching (e.g., dry etching) the laminate using the resist pattern RP2 as a mask until the substrate 104 is exposed.

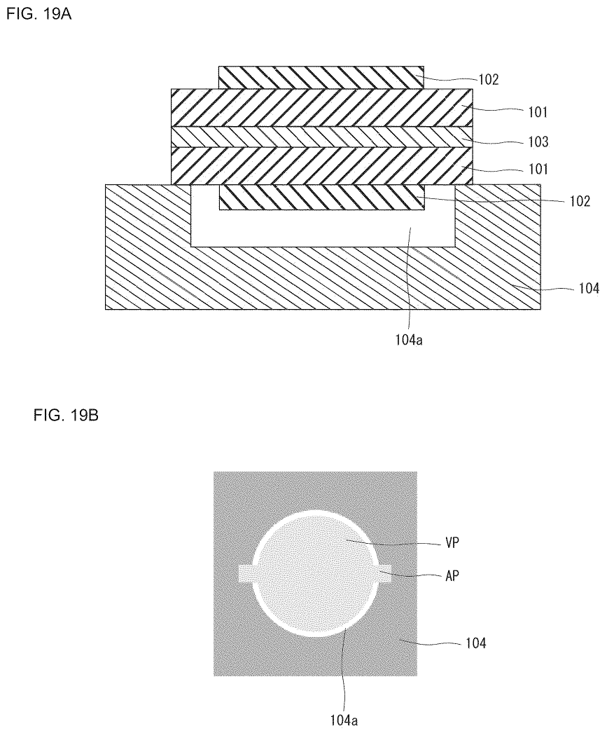

In last Step S12, a gap is formed (see A of FIG. 19 and B of FIG. 19). Specifically, the oxide film OF is removed by etching (e.g., wet etching), such that the gap is formed in the recess part 104a.

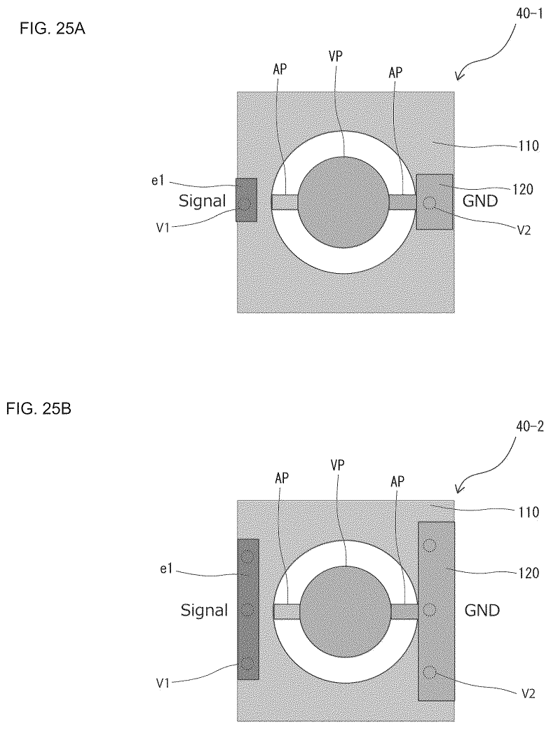

It should be noted that for example after Step S11 or Step S12, an electrode may be formed on the extremity end side of each arm part AP by, for example, lift-off (see FIG. 25).

### <<Effects of Vibration Element According to First Embodiment>>

As it can be seen from the above description, in the vibration element 10, the laminate part in which the first elastic layers are arranged on the both sides of the third elastic layer (base layer) has a bimorph structure (a structure in which one expands and the other contracts). In addition, the vibration element 10 has a structure approximating the bimorph structure in which the second elastic layers are arranged on both sides of the laminate part. Therefore, the vibration element 10 can increase displacement of the first elastic layers and the Villari effect caused in the second elastic layers due to such displacement and can increase displacement of the second elastic layers and the piezoelectric effect caused in the first elastic layers due to such displacement. Accordingly, the vibration element 10 can obtain higher gain while achieving downsizing as compared to the vibration elements of Comparative Examples 1 and 2.

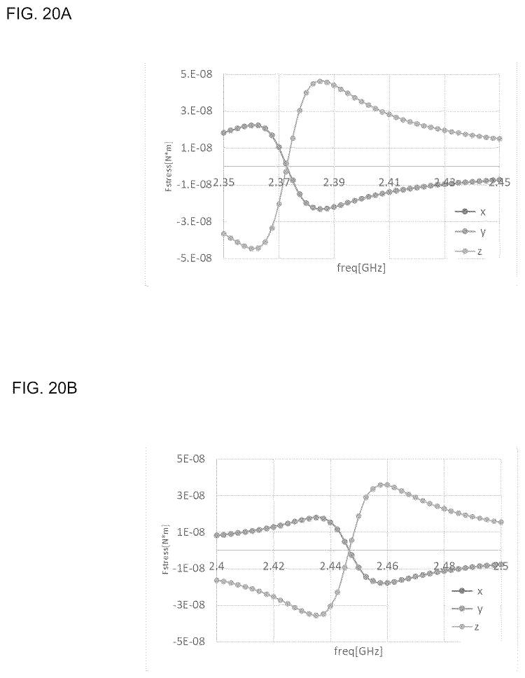

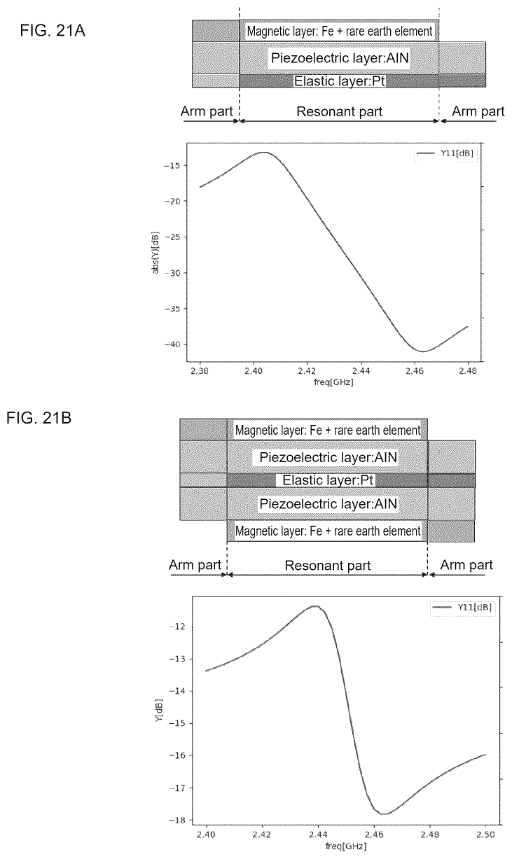

In addition, in a case where the vibration element 10 performs an ideal bimorph operation using the third elastic layer (base layer) as a center, although some of them are repeated, the following effects 1 to 8 can also be obtained with respect to the vibration element 1 according to Comparative Example 1 having the unimorph structure.
1. The composite impedance is about ½.
2. In a case where the same power is input, the voltage is 1/√2 times and the current is √2 times.
3. Since the magnetic moment of each magnetic layer is proportional to the voltage, it is 1/√2 times and it is √2 times for two magnetic layers.
4. Since the two magnetic layers are arranged at an electrically very close distance, the magnetic fields (fields) are synthesized in the same phase.
5. The radiated power is twice because it is ideally proportional to the square of the magnetic moment. At the same time, the radiation efficiency is also twice.
6. Since the resonant frequency deviates as shown in B of FIG. 3, desired displacement does not occur at this frequency. In this regard, the resonant frequency can be made the same and the displacement can be maintained without lowering it by employing the structure in B of FIG. 4. Specifically, since the plurality of first elastic layers 101 has a bimorph structure and the plurality of second elastic layers 102 has a structure approximating the bimorph structure in the vibration element 10, the displacement can be maintained or decrease in the displacement can be suppressed even in a case where the volume has increased.
7. The maximum displacement is maintained and also the stress is larger in the vibration element 10 (B of see FIG. 20) than in the vibration element 1 (A of see FIG. 20).
8. The resonant frequency can also be set to be near a desired frequency (e.g., 2.45 GHZ) (B of see FIG. 21) as in the vibration element 1 according to Comparative Example 1 (A of see FIG. 21) by setting the first elastic layers 101 to have a bimorph structure and setting the second elastic layers 102 to have a structure approximating the bimorph structure.

### SUMMARY

The vibration element 10 according to the first embodiment includes the vibration part VP in which the plurality of layers is laminated, the plurality of layers including a plurality of (e.g., two) first elastic layers 101 which is elastically deformed by electric field application and at least one (e.g., one) second elastic layer 102 which is elastically deformed by magnetic field application. Accordingly, a vibration element having a structure capable of efficiently performing electric field-to-magnetic field conversion can be provided.

### [2. Vibration Element According to Second Embodiment of Present Technology]

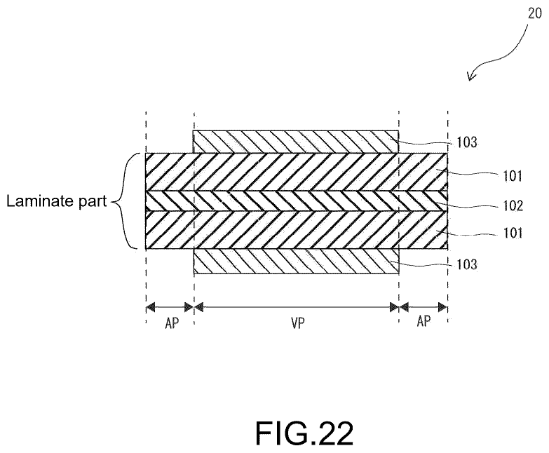

FIG. 22 is a cross-sectional view of a vibration element 20 according to a second embodiment of the present technology. The vibration element 20 has a configuration similar to that of the vibration element 10-1 according to Example 1 of the first embodiment except for the point that the first elastic layers 101 are arranged on both sides of the second elastic layer 102 in the direction of lamination (upper and lower directions) and the third elastic layers 103 are arranged on both sides of the laminate part in the direction of lamination (upper and lower directions), the laminate part including the second elastic layer 102 and the first elastic layers 101 on the both side of the second elastic layer 102.

In the vibration element 20, the first and second elastic layers 101 and 102 are alternately laminated.

The vibration element 20 performs an operation similar to that of the vibration element 10-1 except for the point that the vibration element 20 performs a bimorph operation using the second elastic layer 102 as a center.

In accordance with the vibration element 20, effects similar to those of the vibration element 10-1 can be provided.

### [3. Vibration Element According to Third Embodiment of Present Technology]

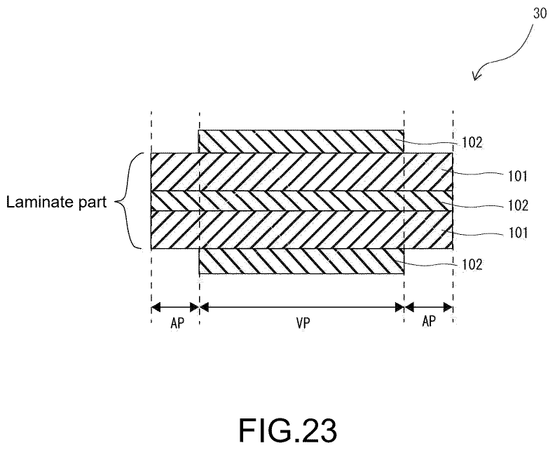

FIG. 23 is a cross-sectional view of a vibration element 30 according to a third embodiment of the present technology. The vibration element 30 has a configuration similar to that of the vibration element 20 according to the second embodiment except for the point that the second elastic layers 102 are arranged on both sides of the laminate part in the direction of lamination (upper and lower directions), the laminate part including the second elastic layer 102 and the first elastic layers 101 on the both side of the second elastic layer 102.

In the vibration element 30, the first and second elastic layers 101 and 102 are alternately laminated.

The vibration element 30 performs an operation similar to that of the vibration element 20.

In accordance with the vibration element 30, effects similar to those of the vibration element 20 can be provided.

[4. Vibration Element According to Fourth embodiment of Present Technology]

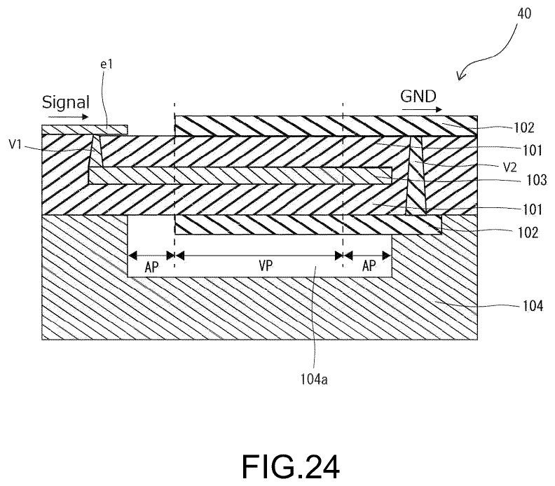

FIG. 24 is a cross-sectional view of a vibration element 40 according to a fourth embodiment of the present technology. The vibration element 40 has a configuration substantially similar to that of the vibration element 10-2 according to Example 2 of the first embodiment except for the point that the third elastic layer 103 is arranged inside the first elastic layers 101.

In the vibration element 40, an external electrode e1 is provided on the upper surface of the first elastic layer 101 (upper piezoelectric layer) and the external electrode e1 and the third elastic layer 103 (base layer) formed of the conductive material are electrically connected to each other via a via-hole V1 provided inside the first elastic layer 101. The external electrode e1 and the via-hole V1 are formed of the same conductive material as the third elastic layer 103 as an example. However, at least one of the external electrode e1 or the via-hole V1 may be formed of a conductive material (e.g., Pt, Ti, Al, Cu, Mo, Au, or Ag) different from that of the third elastic layer 103.

In the vibration element 40, the second elastic layer 102 (upper magnetic layer) formed of a conductive material arranged on the upper side of the first elastic layers 101 in the direction of lamination (upper and lower directions) and the second elastic layers 102 (lower magnetic layer) formed of a conductive material arranged on the lower side of the first elastic layers 101 are electrically connected to each other via a via-hole V2 extending through the first elastic layers 101. The via-hole V2 is, as an example, formed of the same conductive material as the second elastic layers 102. However, the via-hole V2 may be formed of a different conductive material (e.g., Pt, Ti, Al, Cu, Mo, Au, or Ag).

In the vibration element 40, as an example, the external electrode e1 is connected to the power supply and the upper magnetic layer is connected to the ground. However, the external electrode e1 may be connected to the ground and the upper magnetic layer may be connected to the power supply.

The vibration element 40 performs an operation similar to that of the vibration element 10-2 according to Example 2 of the first embodiment.

The vibration element 40 can be manufactured by a manufacturing method compatible with the manufacturing method for the vibration element 10-2 according to Example 2 of the first embodiment.

In accordance with the vibration element 40, effects similar to those of the vibration element 10-2 according to Example 2 of the first embodiment can be provided.

### Example 1

A of FIG. 25 is a plan view of a vibration element 40-1 according to Example 1 of the fourth embodiment of the present technology. In the vibration element 40-1, the external electrode e1 and the third elastic layer 103 with a smaller area are electrically connected to each other via the single via-hole V1, for example, and the upper magnetic layer and the lower magnetic layer with a smaller area are electrically connected to each other via the single via-hole V2, for example. In accordance with the vibration element 40-1, the number of via-holes is less, and the manufacture processes can be simplified.

### Example 2

B of FIG. 25 is a plan view of a vibration element 40-2 according to according to Example 2 of the fourth embodiment of the present technology. In the vibration element 40-2, the external electrode e1 and the third elastic layer 103 with a larger area are electrically connected to each other via three via-holes V1, for example, and the upper magnetic layer and the lower magnetic layer with a larger area are electrically connected via three via-holes V2, for example. In accordance with the vibration element 40-2, the area of the external electrode e1 and the respective magnetic layers can be increased and lower resistance can be provided, and thus power loss can be reduced.

### [5. Vibration Element According to Fifth Embodiment of Present Technology]

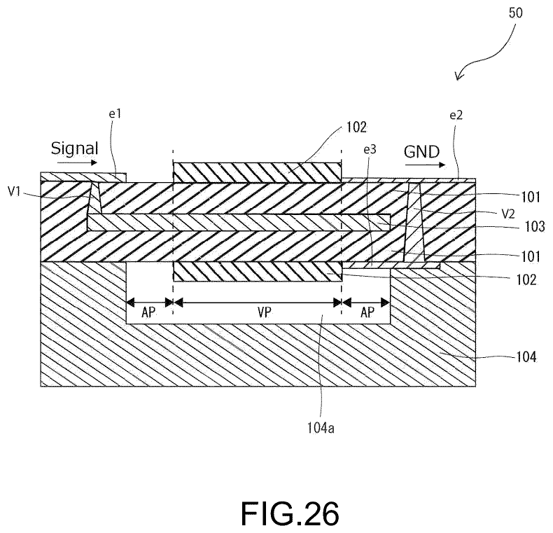

FIG. 26 is a cross-sectional view of a vibration element 50 according to a fifth embodiment of the present technology. The vibration element 50 has a configuration similar to that of the vibration element 40 according to the fourth embodiment except for the point that an external electrode e2 is provided on the first elastic layers 101 separately from the second elastic layer 102 (upper magnetic layer) on the upper side and an internal electrode e3 is provided between the first elastic layers 101 and the substrate 104 separately from the second elastic layer 102 (lower magnetic layer) on the lower side. The external electrode e2 and the internal electrode e3 may be formed of a conductive material, e.g., Pt, Ti, Al, Cu, Mo, Au, or Ag.

The vibration element 50 performs an operation similar to that of the vibration element 10-2 according to Example 2 of the first embodiment.

The vibration element 50 can be manufactured by a manufacturing method compatible with the manufacturing method for the vibration element 10-2 according to Example 2 of the first embodiment.

In accordance with the vibration element 50, effects similar to those of the vibration element 10-2 according to Example 2 of the first embodiment can be provided.

### [6. Vibration Element According to Sixth Embodiment of Present Technology]

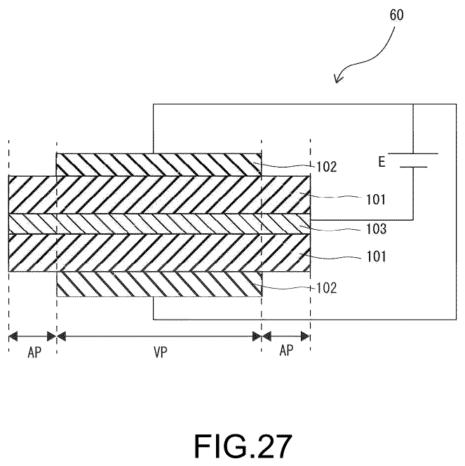

FIG. 27 is a cross-sectional view of a vibration element 60 according to a sixth embodiment of the present technology. In the vibration element 60, the third elastic layer 103 that is formed of a conductive material and also functions as an electrode is connected to one terminal (e.g., a negative electrode terminal) of a power supply E with a wire and the second elastic layers 102 on the upper and lower sides that are formed of conductive magnetic layers and also functions as electrodes are connected to the other terminal (e.g., a positive electrode terminal) of the power supply E. That is, the upper half part and the lower half part of the vibration element 60 are connected in parallel to the power supply E. Although in the example of FIG. 27, the DC power supply is used as the power supply E, the AC power supply may be used.

In the vibration element 60, when the power supply E is powered ON, voltage from the power supply E is applied on each of the first elastic layer 101 on the upper side (upper piezoelectric layer) and the first elastic layer 101 on the lower side (lower piezoelectric layer), and the upper piezoelectric layer and the lower piezoelectric layer can be elastically deformed to perform a bimorph operation.

### Example 1

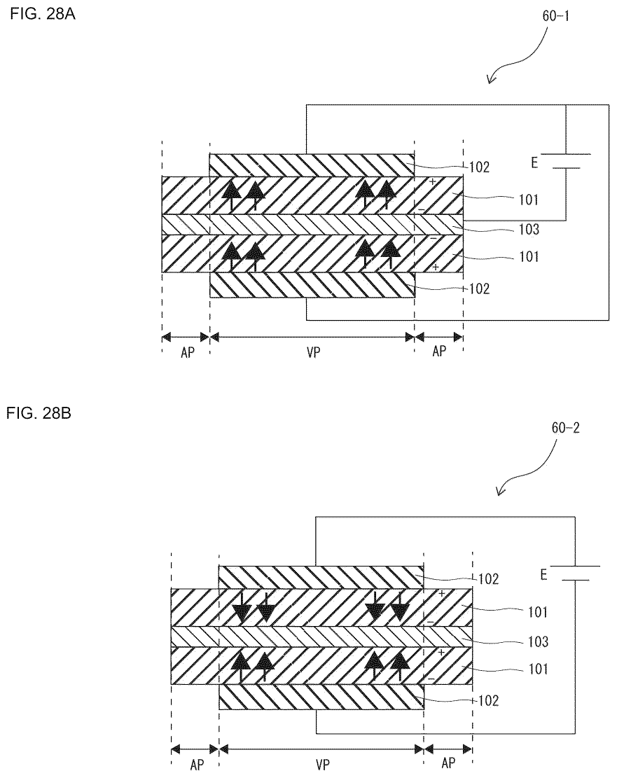

A of FIG. 28 is a cross-sectional view of a vibration element 60-1 according to Example 1 of the sixth embodiment of the present technology. The vibration element 60-1 is connected to the power supply E with a wire as in the vibration element 60 (see FIG. 27). In the vibration element 60-1, polarization is performed so that an end portion on the third elastic layer 103 (base layer) side of each first elastic layer 101 (piezoelectric layer) is negatively charged and an end portion on a side opposite to the third elastic layer 103 side is positively charged. Accordingly, the respective first elastic layers 101 are deformed in the same direction as shown by the arrows in A of FIG. 28. In this manner, the vibration element 60-1 performs an operation of prioritizing parallel-type displacement. Although the DC power supply is used as the power supply E in the example of A of FIG. 28, the AC power supply may be used.

### Example 2

B of FIG. 28 is a cross-sectional view of a vibration element 60-2 according to Example 2 of the sixth embodiment of the present technology. In the vibration element 60-2, the second elastic layer 102 on the upper side of the second elastic layers 102 on the upper and lower sides that are formed of conductive magnetic layers and also function as electrodes is connected to one terminal (e.g., a positive electrode terminal) of the power supply E and the second elastic layer 102 on the lower side is connected to the other terminal (e.g., a negative electrode terminal) of the power supply E. That is, the upper half part and the lower half part of the vibration element 60-2 are connected in series to the power supply E. In the vibration element 60-2, polarization is performed so that an end portion on the third elastic layer 103 (base layer) side of the first elastic layer 101 on the upper side (piezoelectric layer) is negatively charged and an end portion on a side opposite to the third elastic layer 103 side is positively charged. In the vibration element 60-2, polarization is performed so that an end portion on the third elastic layer 103 side of the first elastic layer 101 on the lower side (piezoelectric layer) is positively charged and an end portion on a side opposite to the third elastic layer 103 side is negatively charged. Accordingly, the respective first elastic layers 101 are deformed in different directions as shown by the arrows in B of FIG. 28. In this manner, the vibration element 60-2 performs an operation of prioritizing series-type sensing performance. Although the DC power supply is used as the power supply E in the example of B of FIG. 28, the AC power supply may be used.

### [7. Vibration Element According to Seventh Embodiment of Present Technology]

In a vibration element according to a seventh embodiment, the first elastic layers 101 are arranged on the both sides of the third elastic layer 103 which is a layer positioned in middle in the direction of lamination and the first elastic layers 101 can be different from each other in thickness and/or material. In the vibration element according to the seventh embodiment, the second elastic layers 102 are arranged on the both sides of the third elastic layer 103 which is a layer positioned in middle in the direction of lamination and the second elastic layers 102 can be different from each other in thickness and/or material. In accordance with the vibration element according to the seventh embodiment, a frequency band in which response is possible (a frequency band in which the resonant frequency is present) can be extended.

### Example 1

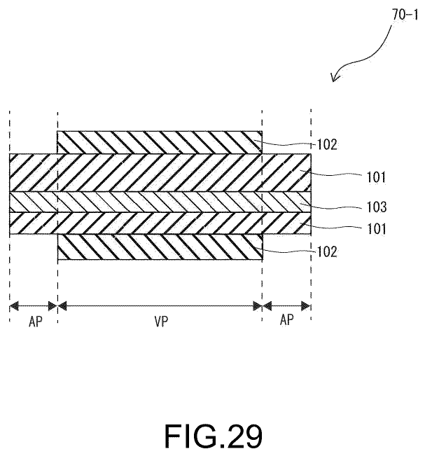

FIG. 29 is a cross-sectional view of a vibration element 70-1 according to Example 1 of the seventh embodiment of the present technology. The vibration element 70-1 has a configuration similar to that of the vibration element 10-1 according to Example 1 of the first embodiment except for the point that at least a thickness of the thickness and material of the first elastic layers 101 (e.g., piezoelectric layers) on the upper and lower sides is different. In the vibration element 70-1, the first elastic layer 101 on the lower side is thinner than the first elastic layer 101 on the upper side. However, the first elastic layer 101 on the lower side may be thicker than the first elastic layer 101 on the upper side.

### Example 2

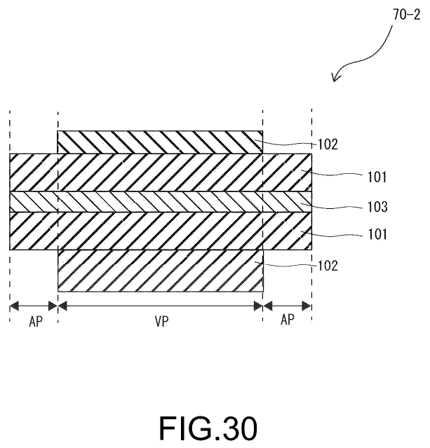

FIG. 30 is a cross-sectional view of a vibration element 70-2 according to Example 2 of the seventh embodiment of the present technology. The vibration element 70-2 has a configuration similar to that of the vibration element 10-1 according to Example 1 of the first embodiment except for the point that the thickness of the second elastic layers 102 (e.g., magnetic layers) on the upper and lower sides is different. In the vibration element 70-2, the second elastic layer 102 on the lower side is thicker than the second elastic layer 102 on the upper side. However, the second elastic layer 102 on the lower side may be thinner than the second elastic layer 102 on the upper side.

### Example 3

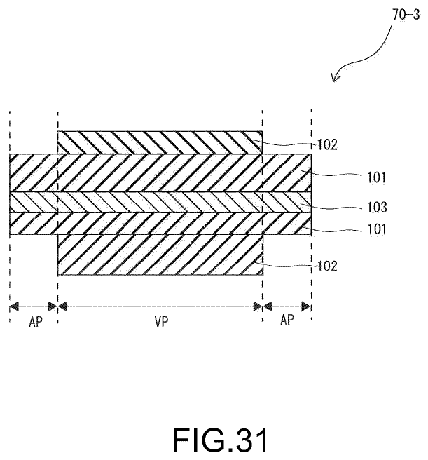

FIG. 31 is a cross-sectional view of a vibration element 70-3 according to Example 3 of the seventh embodiment of the present technology. The vibration element 70-3 has a configuration similar to that of the vibration element 10-1 according to Example 1 of the first embodiment except for the point that the thickness of the first elastic layers 101 (e.g., piezoelectric layers) on the upper and lower sides is different and the thickness of the second elastic layers 102 (e.g., magnetic layers) on the upper and lower sides are different. In the vibration element 70-3, the first elastic layer 101 on the lower side is thinner than the second elastic layer 101 on the upper side. However, the first elastic layer 101 on the lower side may be thicker than the second elastic layer 101 on the upper side. In the vibration element 70-3, the second elastic layer 102 on the lower side is thicker than the second elastic layer 102 on the upper side. However, the second elastic layer 102 on the lower side may be thinner than the second elastic layer 102 on the upper side.

### [8. Vibration Element According to Eighth Embodiment of Present Technology]

A vibration element according to an eighth embodiment has a configuration similar to that of the vibration element 10-1 according to Example 1 of the first embodiment except for the point that the vibration element includes a resonance adjustment layer. In accordance with the vibration element according to the eighth embodiment, for example, when the resonant frequency deviates from a desired frequency in the mechanical design of the vibration element 10-1 alone, the resonance adjustment layer can adjust the deviation to be reduced (to be favorably about 0).

### Example 1

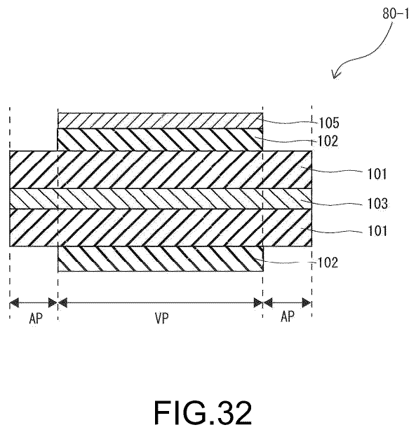

FIG. 32 is a cross-sectional view of a vibration element 80-1 according to Example 1 of the eighth embodiment of the present technology. In the vibration element 80-1, a resonance adjustment layer 105 is provided on the upper surface of the vibration part VP (specifically, the upper surface of the second elastic layer 102 on the upper side). Since the resonance adjustment layer 105 also serves as an electrode, it is formed of a conductive material such as metal such as Al, Cu, or Pb, for example. The resonance adjustment layer 105 may be provided on the lower surface of the vibration part VP (specifically, the lower surface of the second elastic layer 102 on the lower side).

### Example 2

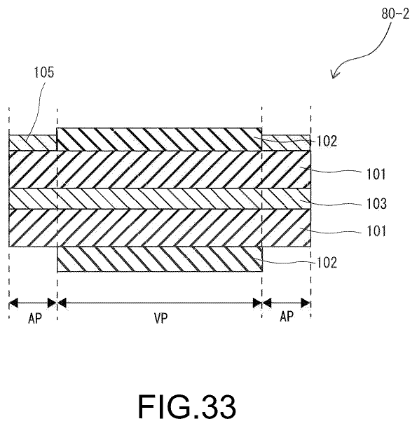

FIG. 33 is a cross-sectional view of a vibration element 80-2 according to Example 2 of the eighth embodiment of the present technology. In the vibration element 80-2, the resonance adjustment layer 105 is provided on the upper surface of the arm part AP. The resonance adjustment layer 105 is formed of an insulating material, e.g., an insulation resin or an insulation magnetic material, in order to suppress current leakage from the vibration part VP side to the arm part AP side. The resonance adjustment layer 105 may be provided on the lower surface of the arm part AP.

### Example 3

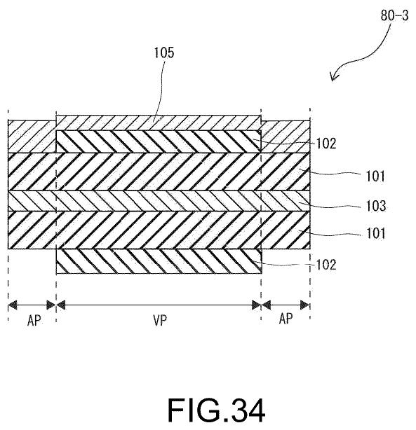

FIG. 34 is a cross-sectional view of a vibration element 80-3 according to Example 3 of the eighth embodiment of the present technology. In the vibration element 80-3, the resonance adjustment layer 105 is provided over the upper surface of the vibration part VP and the upper surface of the arm part AP. The resonance adjustment layer 105 also serves as an electrode and is formed of, for example, a non-conductive magnetic material in order to suppress current leakage from the vibration part VP side to the arm part AP side. The resonance adjustment layer 105 may be provided over the lower surface of the vibration part VP and the lower surface of the arm part AP.

### [9. Array of Vibration Elements According to Ninth Embodiment of Present Technology]

An array of vibration elements according to a ninth embodiment is configured in such a manner that a plurality of vibration elements is arranged in an array form. In accordance with the array of the vibration elements according to the ninth embodiment, effects similar to those of the conventional antenna array can be provided and a vibration element array capable of efficiently using the installable space can be provided.

### Example 1

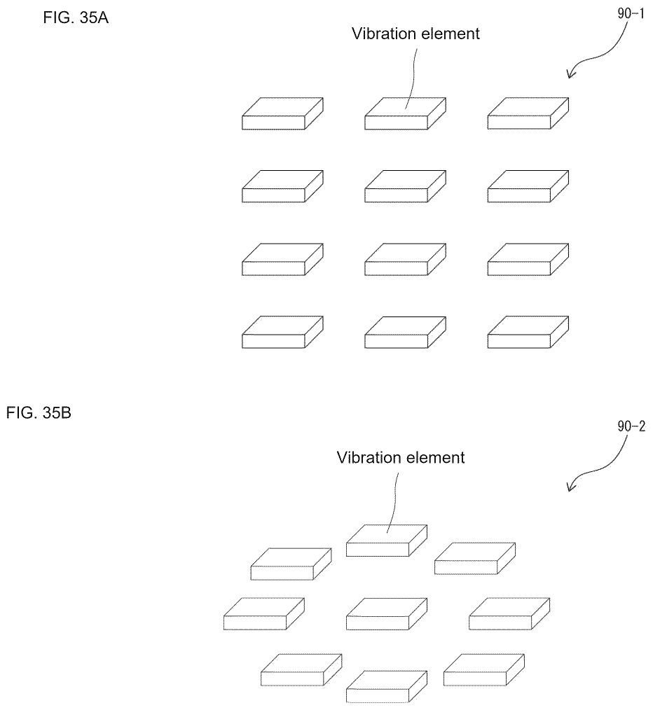

A of FIG. 35 is a perspective view of a vibration element array 90-1 according to Example 1 of the ninth embodiment. In the vibration element array 90-1, a plurality of vibration elements according to any one of the first to eighth embodiments is arranged in a matrix form on a rectangular installation region. The respective vibration elements are supported by the supporting structure via a plurality of arm parts so that vibration parts are capable of vibrating.

### Example 2

B of FIG. 35 is a perspective view of a vibration element array 90-2 according to Example 2 of the ninth embodiment. In the vibration element array 90-2, a plurality of vibration elements according to any one of the first to eighth embodiments is arranged on a circular installation region. The respective vibration elements are supported by the supporting structure via a plurality of arm parts so that vibration parts are capable of vibrating.

### [10. Vibration Element According to Tenth Embodiment of Present Technology]

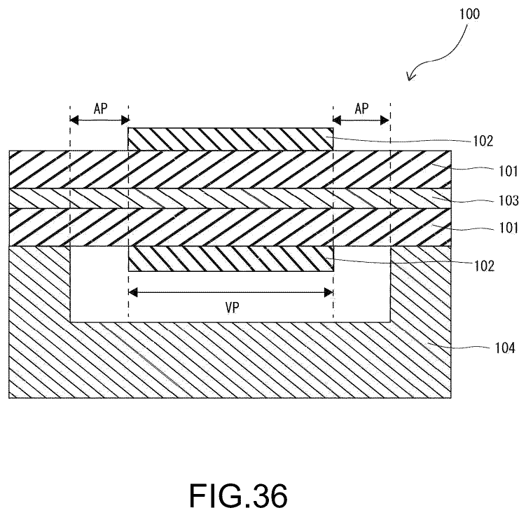

FIG. 36 is a cross-sectional view of a vibration element 100 according to a tenth embodiment. The vibration element 100 has a configuration similar to that of the vibration element 10-2 according to Example 2 of the first embodiment except for the point that the arm part AP is relatively long.

### Example 1

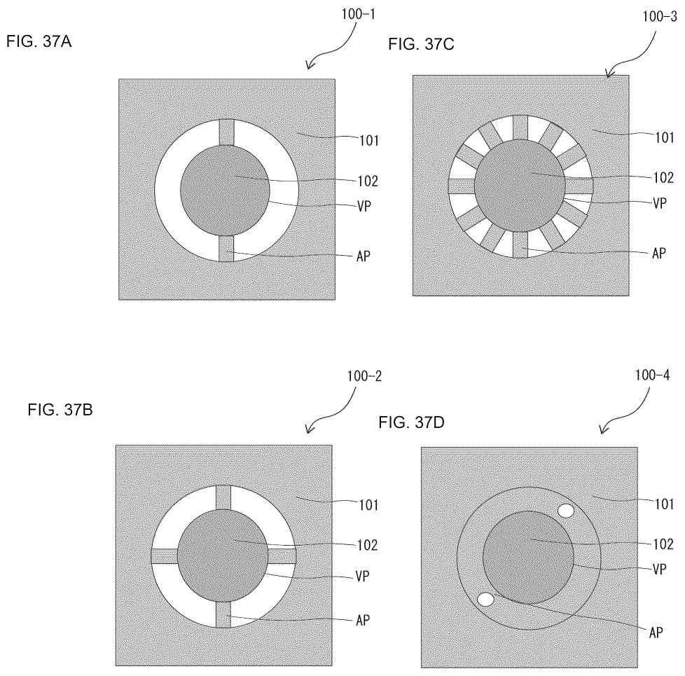

A of FIG. 37 is a plan view of a vibration element 100-1 according to Example 1 of the tenth embodiment of the present technology. In the vibration element 100-1, each of two opposite end portions of the vibration part VP is supported by the supporting structure via the arm part AP.

### Example 2

B of FIG. 37 is a plan view of a vibration element 100-2 according to Example 2 of the tenth embodiment of the present technology. In the vibration element 100-2, each of four end portions of the vibration part VP which are arranged at equal intervals in the circumferential direction is supported by the supporting structure via the arm part AP.

### Example 3

C of FIG. 37 is a plan view of a vibration element 100-3 according to Example 3 of the tenth embodiment of the present technology. In the vibration element 100-3, each of twelfth end portions which are arranged at equal intervals in the circumferential direction of the vibration part VP is supported by the supporting structure via the arm part AP.

### Example 4

D of FIG. 37 is a plan view of a vibration element 100-4 according to Example 4 of the tenth embodiment of the present technology. In the vibration element 100-4, a portion between an aperture provided near the outside of each of the two opposite end portions of the vibration part VP and the vibration part VP is the arm part AP.

### Example 5

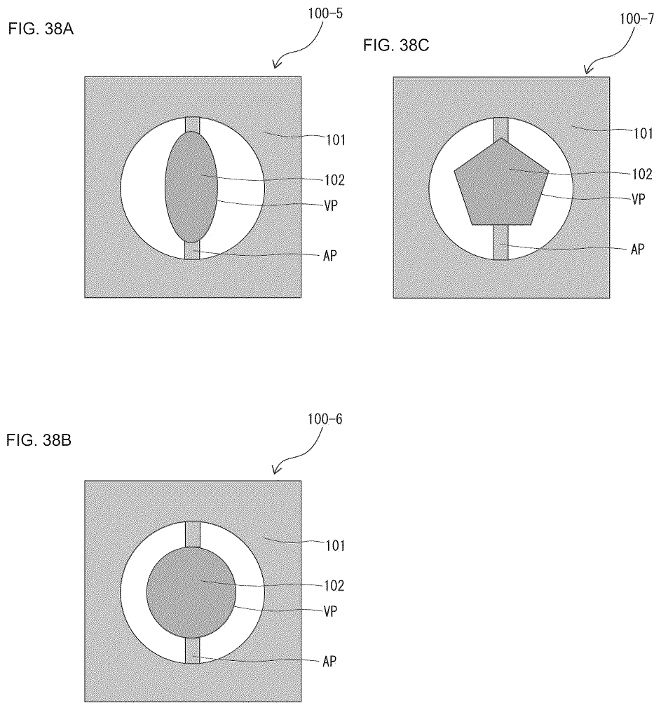

A of FIG. 38 is a plan view of a vibration element 100-5 according to Example 5 of the tenth embodiment of the present technology. In the vibration element 100-5, each of two opposite end portions in a longitudinal direction of the vibration part VP whose planar-view shape is an elliptical shape is supported by the supporting structure via the arm part AP.

### Example 6

B of FIG. 38 is a plan view of a vibration element 100-6 according to Example 6 of the tenth embodiment of the present technology. In the vibration element 100-6, each of two opposite end portions of the vibration part VP whose planar-view shape is a circular shape is supported by the supporting structure via the arm part AP.

### Example 7

C of FIG. 38 is a plan view of a vibration element 100-7 according to Example 7 of the tenth embodiment of the present technology. In the vibration element 100-7, each of two opposite end portions of the vibration part VP whose planar-view shape is a polygonal shape (e.g., pentagon) is supported by the supporting structure via the arm part AP.

### Example 8

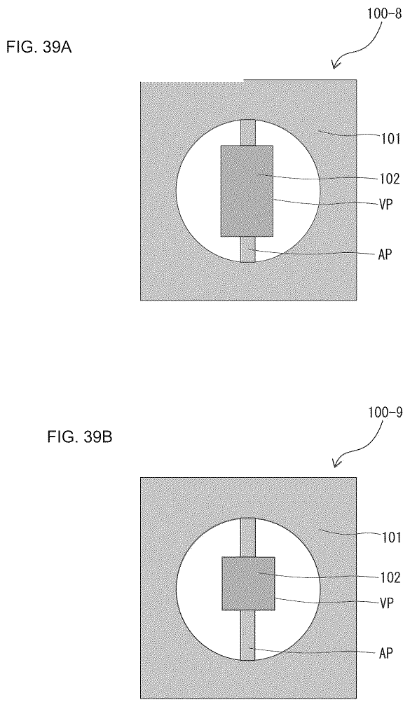

A of FIG. 39 is a plan view of a vibration element 100-8 according to Example 8 of the tenth embodiment of the present technology. In the vibration element 100-8, each of the two opposite end portions in the longitudinal direction of the vibration part VP whose planar-view shape is a rectangular shape is supported by the supporting structure via the arm part AP.

### Example 9

B of FIG. 39 is a plan view of a vibration element 100-9 according to Example 9 of the tenth embodiment of the present technology. In the vibration element 100-9, each of two opposite end portions of the vibration part VP whose planar-view shape is a square shape is supported by the supporting structure via the arm part AP.

### Example 10

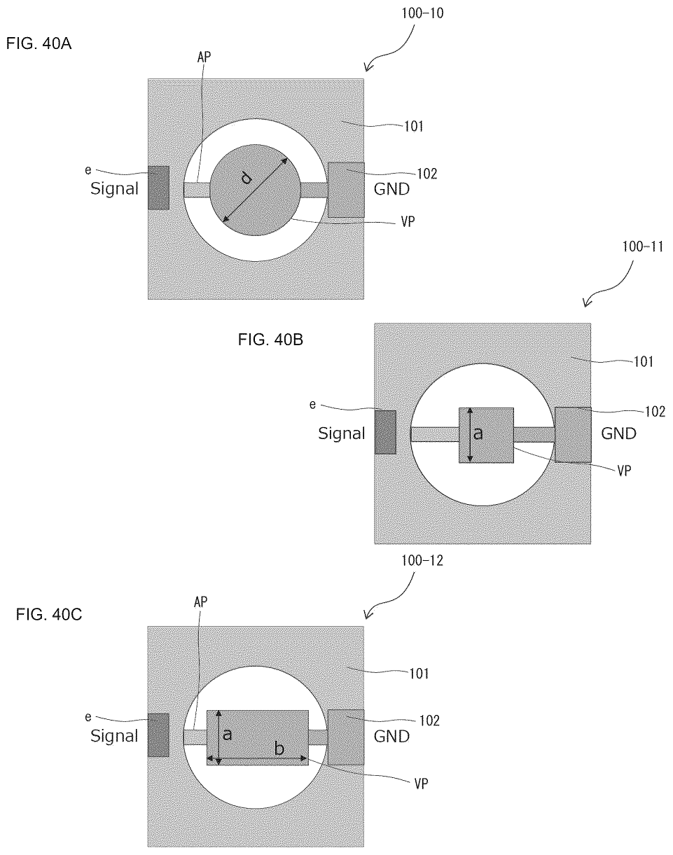

A of FIG. 40 is a plan view of a vibration element 100-10 according to Example 10 of the tenth embodiment of the present technology. In the vibration element 100-10, each of two opposite end portions of the vibration part VP whose planar-view shape is a circular shape with a diameter d (e.g., 200 μm) is supported by the supporting structure via the arm part AP.

### Example 11

B of FIG. 40 is a plan view of a vibration element 100-11 according to Example 11 of the tenth embodiment of the present technology. In the vibration element 100-11, each of two opposite end portions of the vibration part VP whose planar-view shape is a square shape with one side having a length a (e.g., 200 μm) is supported by the supporting structure via the arm part AP.

### Example 12

C of FIG. 40 is a plan view of a vibration element 100-12 according to Example 12 of the tenth embodiment of the present technology. In the vibration element 100-12, each of the two opposite end portions in the longitudinal direction of the vibration part VP whose planar-view shape is a rectangular shape with a shorter side having a length a (e.g., 100 μm) and a longer side having a length b (e.g., 200 μm) is supported by the supporting structure via the arm part AP.

### [11. Vibration Element According to Eleventh Embodiment of Present Technology]

A vibration element according to an eleventh embodiment of the present technology has a configuration similar to that of the vibration element 10-1 according to Example 1 of the first embodiment except for the point that the second elastic layer 102 includes magnetic layers having magnetostrictive properties and insulating layers, which are alternately laminated. In accordance with the vibration element according to the eleventh embodiment, it is possible to control a direction of the magnetic field in the second elastic layers 102 to confine energy of the magnetic field. As a result, characteristics and gain are improved.

### Example 1

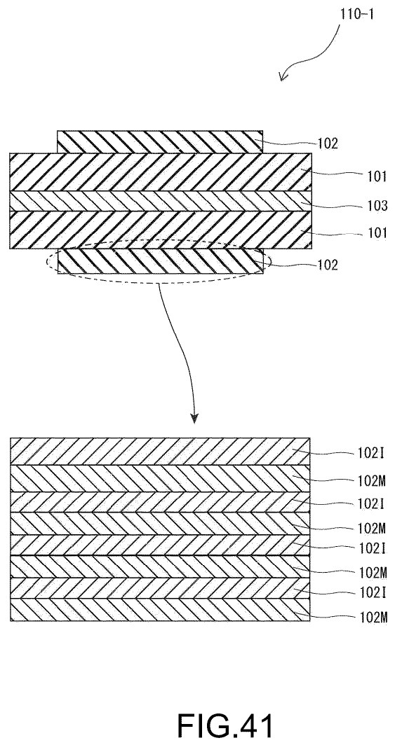

FIG. 41 is a cross-sectional view of a vibration element 110-1 according to Example 1 of the eleventh embodiment of the present technology. In the vibration element 110-1, the second elastic layer 102 has a laminate structure including magnetic layers 102M having magnetostrictive properties (e.g., soft magnetic material whose magnetostriction constant is not zero) and insulating layers 102I, which are alternately laminated.

### Example 2

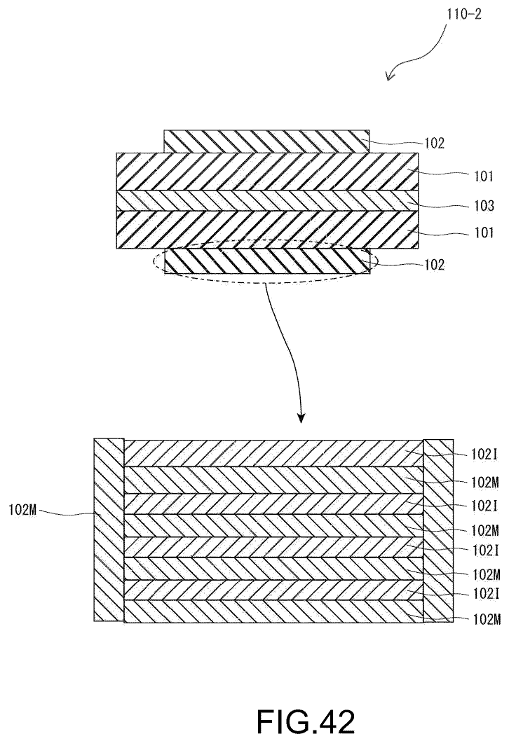

FIG. 42 is a cross-sectional view of a vibration element 110-2 according to Example 2 of the eleventh embodiment of the present technology. The vibration element 110-2 has a configuration similar to that according to Example 1 of the vibration element 110-1 except for the point that the second elastic layer 102 also includes magnetic layers 102M on both sides of the laminate structure in the in-plane direction.

### Example 3

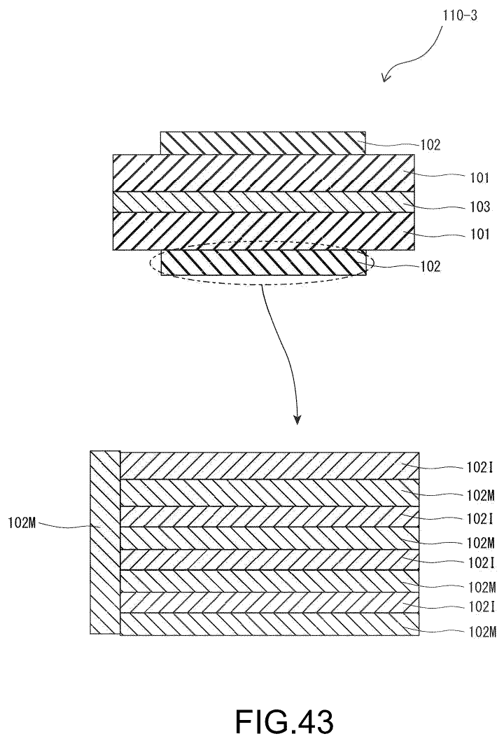

FIG. 43 is a cross-sectional view of a vibration element 110-3 according to Example 3 of the eleventh embodiment of the present technology. The vibration element 110-3 has a configuration similar to that according to Example 1 of the vibration element 110-1 except for the point that the second elastic layer 102 also includes a magnetic layer 102M on one side of the laminate structure in the in-plane direction.

### Example 4

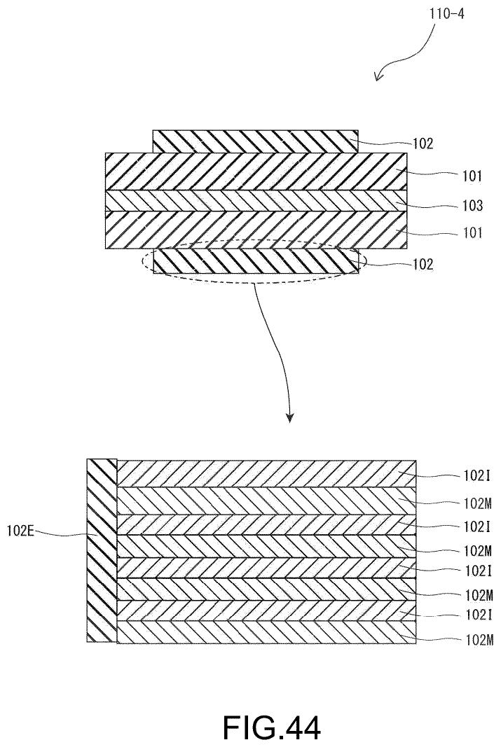

FIG. 44 is a cross-sectional view of a vibration element 110-4 according to Example 4 of the eleventh embodiment of the present technology. The vibration element 110-4 has a configuration similar to that according to Example 1 of the vibration element 110-1 except for the point that the second elastic layer 102 includes an electrode 102E formed of a conductive material on one side of the laminate structure in the in-plane direction.

### [12. Vibration Element According to Twelfth Embodiment of Present Technology]

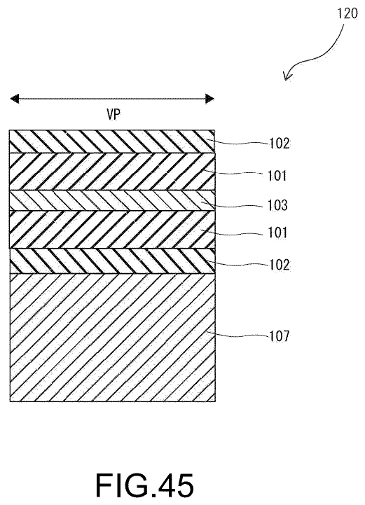

FIG. 45 is a cross-sectional view of a vibration element 120 according to a twelfth embodiment of the present technology. The vibration element 120 has a configuration similar to that of the vibration element 10-1 according to Example 1 of the first embodiment except for the point that a reflective layer 107 is provided on the lower surface of the second elastic layer 102 on the lower side. In the vibration element 120, the reflective layer 107 has a function of reflecting acoustic vibrations on the lower surface to enhance displacement and stress of the vibration part VP.

As it can be seen from the above description of the embodiments, the vibration element according to the present technology is significantly suitable for mounting a compact electronic apparatus (e.g., earphones) as an antenna element with super compact and high performance as an example. Moreover, the vibration element according to the present technology can also be used for applications, for example, where an energy harvester for a room wall, a wall surface of a casing of an electronic apparatus, or the like is required.

It should be noted that the configurations of the vibration elements according to the above-mentioned embodiments can be changed as appropriate. For example, the vibration element may include a layer other than the above-mentioned first to third elastic layers, substrate, and reflective layer. For example, the configurations of some of the vibration elements according to the above-mentioned embodiments may be combined to the extent that they do not contradict each other.

Moreover, the present technology can also take the following configurations.

(1) A vibration element, including
a vibration part in which a plurality of layers is laminated, the plurality of layers including
   a plurality of first elastic layers that is elastically deformed by electric field application, and
   at least one second elastic layer that is elastically deformed by magnetic field application.

(2) The vibration element according to (1), in which
the first elastic layers each generate an electric field when the first elastic layers are elastically deformed by elastic deformation of the second elastic layer, and
the second elastic layer generates a magnetic field when the second elastic layer is elastically deformed by elastic deformation of the first elastic layer.

(3) The vibration element according to (1) or (2), in which
the first elastic layers are not adjacent to each other.

(4) The vibration element according to any one of (1) to (3), in which
the second elastic layer includes a plurality of second elastic layers, and
the second elastic layers are not adjacent to each other.

(5) The vibration element according to any one of (1) to (4), in which
the plurality of layers includes a third elastic layer, and
the first elastic layers are arranged on both sides of the third elastic layer.

(6) The vibration element according to (5), in which
the second elastic layers include a plurality of second elastic layers, and
the second elastic layers are arranged on both sides of a laminate part including the third elastic layer and the first elastic layers on the both sides of the third elastic layer.

(7) The vibration element according to any one of (1) to (6), in which
the first and second elastic layers are alternately laminated.

(8) The vibration element according to any one of (1) to (7), in which
the first elastic layers are arranged on both sides of the second elastic layer.

(9) The vibration element according to (7) or (8), in which
the plurality of layers includes third elastic layers arranged on both sides of a laminate part including the second elastic layer and first elastic layers on both sides of the second elastic layer.

(10) The vibration element according to any one of (7) to (9), in which
the second elastic layers are at least three second elastic layers, and
the second elastic layers are arranged on both sides of the laminate part including the second elastic layer and first elastic layers arranged on both sides of the second elastic layer.

(11) The vibration element according to any one of (1) to (10), in which
the first elastic layers are arranged on both sides of a layer that is positioned in middle of the plurality of layers in a direction of lamination, and
the first elastic layers are different from each other in thickness and/or material.

(12) The vibration element according to any one of (1) to (11), in which
the second elastic layer includes a plurality of second elastic layers,
the second elastic layers are arranged on both sides of a layer positioned in middle of the plurality of layers in a direction of lamination, and
the second elastic layers are different from each other in thickness and/or material.

(13) The vibration element according to any one of (1) to (12), in which
the plurality of layers includes a resonance adjustment layer.

(14) The vibration element according to any one of (1) to (13), further including:
a plurality of arm parts extending from the vibration part; and
a supporting structure that supports the vibration part to be capable of vibrating via the plurality of arm parts.

(15) The vibration element according to (14), in which
the supporting structure includes a supporting member that has a recess part in which a part of the vibration part is arranged, and
a portion including an extremity end of each of the plurality of arm parts is connected to an opening end of the recess part.

(16) The vibration element according to any one of (1) to (15), in which
the first elastic layers each include a piezoelectric layer.

(17) The vibration element according to any one of (1) to (16), in which
the second elastic layer includes a magnetic layer having magnetostrictive properties.

(18) The vibration element according to (5), in which
the third elastic layer includes a non-piezoelectric layer.

(19) The vibration element according to (9), in which
the third elastic layer includes a non-piezoelectric layer.

(20) The vibration element according to any one of (1) to (19), in which
the second elastic layer includes a magnetic layer having magnetostrictive properties and an insulating layer, the magnetic layer and the insulating layer being alternately laminated.

(21) The vibration element according to any one of (1) to (20), in which
the vibration element is an antenna element.

(22) The vibration element according to any one of (1) to (21), which is operable near a band of 2.45 GHZ.

(23) A vibration element array including a plurality of vibration elements according to any one of (1) to (22) arranged in an array form.

(24) An electronic apparatus including a vibration element according to any one of (1) to (22).

(25) An electronic apparatus including a vibration element array according to (23).

### REFERENCE SIGNS LIST

10, 10-1, 10-2, 20, 30, 40, 40-1, 40-2, 50, 60, 60-1, 60-2, 70-1 to 70-3, 80-1 to 80-3, 100, 100-1 to 100-12, 110-1 to 110-4, 120: vibration element, 90-1, 90-2: vibration element array, 101: first elastic layer, 102: second elastic layer, 102M: magnetic layer, 102I: insulating layer, 103: third elastic layer, 104: substrate (supporting member), 104a: recess part, VP: vibration part, AP: arm part

1. A vibration element, comprising
a vibration part in which a plurality of layers is laminated, the plurality of layers including
a plurality of first elastic layers that is elastically deformed by electric field application, and
at least one second elastic layer that is elastically deformed by magnetic field application.

2. The vibration element according to claim 1, wherein
the first elastic layers each generate an electric field when the first elastic layers are elastically deformed by elastic deformation of the second elastic layer, and
the second elastic layer generates a magnetic field when the second elastic layer is elastically deformed by elastic deformation of the first elastic layer.

3. The vibration element according to claim 1, wherein
the first elastic layers are not adjacent to each other.

4. The vibration element according to claim 1, wherein
the second elastic layer includes a plurality of second elastic layers, and
the second elastic layers are not adjacent to each other.

5. The vibration element according to claim 1, wherein
the plurality of layers includes a third elastic layer, and
the first elastic layers are arranged on both sides of the third elastic layer.

6. The vibration element according to claim 5, wherein
the second elastic layers include a plurality of second elastic layers, and
the second elastic layers are arranged on both sides of a laminate part including the third elastic layer and the first elastic layers on the both sides of the third elastic layer.

7. The vibration element according to claim 1, wherein
the first and second elastic layers are alternately laminated.

8. The vibration element according to claim 1, wherein
the first elastic layers are arranged on both sides of the second elastic layer.

9. The vibration element according to claim 8, wherein
the plurality of layers includes third elastic layers arranged on both sides of a laminate part including the second elastic layer and first elastic layers on both sides of the second elastic layer.

10. The vibration element according to claim 8, wherein
the second elastic layers are at least three second elastic layers, and
the second elastic layers are arranged on both sides of the laminate part including the second elastic layer and first elastic layers on both sides of the second elastic layer.

11. The vibration element according to claim 1, wherein
the first elastic layers are arranged on both sides of a layer that is positioned in middle of the plurality of layers in a direction of lamination, and
the first elastic layers are different from each other in thickness and/or material.

12. The vibration element according to claim 1, wherein
the second elastic layer includes a plurality of second elastic layers,
the second elastic layers are arranged on both sides of a layer positioned in middle of the plurality of layers in a direction of lamination, and
the second elastic layers are different from each other in thickness and/or material.

13. The vibration element according to claim 1, wherein
the plurality of layers includes a resonance adjustment layer.

14. The vibration element according to claim 1, further comprising:
a plurality of arm parts extending from the vibration part; and
a supporting structure that supports the vibration part to be capable of vibrating via the plurality of arm parts.

15. The vibration element according to claim 14, wherein
the supporting structure includes a supporting member that has a recess part in which a part of the vibration part is arranged, and
a portion including an extremity end of each of the plurality of arm parts is connected to an opening end of the recess part.

16. The vibration element according to claim 1, wherein
the first elastic layers each include a piezoelectric layer.

17. The vibration element according to claim 1, wherein
the second elastic layer includes a magnetic layer having magnetostrictive properties.

18. The vibration element according to claim 5, wherein
the third elastic layer includes a non-piezoelectric layer.

19. The vibration element according to claim 9, wherein
the third elastic layer includes a non-piezoelectric layer.

20. The vibration element according to claim 1, wherein
the second elastic layer includes a magnetic layer having magnetostrictive properties and an insulating layer, the magnetic layer and the insulating layer being alternately laminated.

21. The vibration element according to claim 1, wherein
the vibration element is an antenna element.

22. The vibration element according to claim 21, which is operable near a band of 2.45 GHZ.

23. A vibration element array comprising a plurality of vibration elements according to claim 1 arranged in an array form.

24. An electronic apparatus comprising a vibration element according to claim 1.
